(19) United States
(12) Patent Application Publication
(10) Pub. No.: US 2026/0223597 A1
(43) Pub. Date: Jul. 30, 2026

(54) HAPTIC FEDBACK COMPONENT AND HAPTIC FEEDBACK DISPLAY DEVICE

(71) Applicants: Beijing BOE Technology Development Co., Ltd., Beijing (CN); BOE Technology Group Co., Ltd., Beijing (CN)

(72) Inventors: Jijing HUANG, Beijing (CN); He WANG, Beijing (CN); Jiawen ZHANG, Beijing (CN); Zongmin LIU, Beijing (CN)

(21) Appl. No.: 19/146,244

(22) PCT Filed: Sep. 30, 2024
(86) PCT No.: PCT/CN2024/122836

§ 371 Date: Jul. 8, 2025

(30) Foreign Application Priority Data
Dec. 28, 2023 (WO) PCT/CN2023/142933

(51) Int. Cl. H10N 30/20; G06F 3/01; H10N 30/88; H10N 39/00

(52) U.S. Cl. CPC H10N 30/2047; G06F 3/016; H10N 30/88; H10N 39/00

(57) ABSTRACT

Disclosed are a haptic feedback component and a haptic feedback display device, including a flexible circuit board, including: a flexible substrate, a first metal layer, and a second metal layer; the first metal layer includes a plurality of connection pad groups, and the second metal layer includes at least one input pad group; a plurality of piezoelectric actuators, arranged on a side of the first metal layer facing away from the flexible substrate, where each of the plurality of piezoelectric actuators is electrically connected to one of the plurality of connection pad groups; the plurality of piezoelectric actuators are divided into at least one group, the piezoelectric actuators in a same group are electrically connected to a same input pad group, and the piezoelectric actuators in different groups are electrically connected to different input pad groups.

### CROSS-REFERENCE OF RELATED APPLICATIONS

The present application is a national phase entry under 35 U.S.C § 371 of International Application No. PCT/CN2024/122836, filed on Sep. 30, 2024, which claims the priority from International Patent Application No. PCT/CN2023/142933, filed with the China National Intellectual Property Administration on Dec. 28, 2023 and entitled “Haptic Feedback Component and Haptic Feedback Device”, which is hereby incorporated by reference in its entirety.

### TECHNICAL FIELD

The present disclosure relates to the technical field of haptic feedback, and in particular to a haptic feedback component and a haptic feedback display device.

### BACKGROUND

Haptic feedback (Haptics) is the focus of current technology development. Specifically, haptic feedback enables the terminal to interact with the human body through touch.

### SUMMARY

The present disclosure provides a haptic feedback component and a haptic feedback display device, and the solutions are as follows.

Embodiments of the present disclosure provide a haptic feedback component, including:
a flexible circuit board, including: a flexible substrate, a first metal layer arranged on a first surface of the flexible substrate, and a second metal layer arranged on a second surface of the flexible substrate; where the first surface and the second surface are arranged opposite to each other along a thickness direction of the flexible substrate; the first metal layer includes a plurality of connection pad groups, and the second metal layer includes at least one input pad group;
a plurality of piezoelectric actuators, arranged on a side of the first metal layer facing away from the flexible substrate, where each of the plurality of piezoelectric actuators is electrically connected to one of the plurality of connection pad groups; the plurality of piezoelectric actuators are divided into at least one group, the piezoelectric actuators in a same group are electrically connected to a same input pad group, and the piezoelectric actuators in different groups are electrically connected to different input pad groups; the plurality of piezoelectric actuators are configured to generate haptic feedback in response to a drive signal input by the at least one input pad group.

In some embodiments, in the haptic feedback component provided by the present disclosure, each of the plurality of piezoelectric actuators is provided with a positive-polarity lead-out structure and a negative-polarity lead-out structure on a side facing the first metal layer;
each of the plurality of connection pad groups includes a positive-polarity connection pad and a negative-polarity connection pad; and
the positive-polarity lead-out structure is electrically connected to the positive-polarity connection pad, and the negative-polarity lead-out structure is electrically connected to the negative-polarity connection pad;
each of the at least one input pad group includes a positive-polarity input pad, the first metal layer further includes a positive-polarity wiring, and the second metal layer further includes a positive-polarity lead wire;
each of the positive-polarity connection pads electrically connected to the piezoelectric actuators in the same group is electrically connected to a corresponding positive-polarity input pad by means of at least one positive-polarity wiring and at least one positive-polarity lead wire.

In some embodiments, in the haptic feedback component provided by the present disclosure, each of the at least one input pad group further includes a negative-polarity input pad, the first metal layer further includes a negative-polarity wiring, and the second metal layer further includes a negative-polarity lead wire;
each of the negative-polarity connection pads electrically connected to the piezoelectric actuators in the same group is electrically connected to a corresponding negative-polarity input pad by means of at least one negative-polarity wiring and at least one negative-polarity lead wire.

In some embodiments, in the haptic feedback component provided by the present disclosure, the positive-polarity wiring and the positive-polarity lead wire electrically connected to the piezoelectric actuators in the same group are electrically connected by means of a via hole penetrating through the flexible substrate; and
the negative-polarity wiring and the negative-polarity lead wire electrically connected to the piezoelectric actuators in the same group are electrically connected by means of a via hole penetrating through the flexible substrate.

In some embodiments, in the haptic feedback component provided by the present disclosure, the flexible circuit board includes a hollow region and a solid region surrounding the hollow region, and the plurality of connection pad groups are arranged around the hollow region;
the solid region includes a first solid region and a second solid region located on opposite sides of the hollow region in a first direction, and the solid region further includes a third solid region and a fourth solid region located on opposite sides of the hollow region in a second direction, and the first direction is perpendicular to the second direction;
   the plurality of piezoelectric actuators include: a first group of piezoelectric actuators located in the first solid region and the second solid region, and a second group of piezoelectric actuators located in the third solid region and the fourth solid region;
   the plurality of piezoelectric actuators in the first solid region are arranged in at least one row, and the plurality of piezoelectric actuators in the second solid region are arranged in at least one row, and the plurality of piezoelectric actuators in each row are arranged in sequence along the second direction;
   the plurality of piezoelectric actuators in the third solid region are arranged in at least one column, and the plurality of piezoelectric actuators in the fourth solid region are arranged in at least one column, and the plurality of piezoelectric actuators in each column are arranged in sequence along the first direction.

In some embodiments, in the haptic feedback component provided by the present disclosure, the positive-polarity wiring and the negative-polarity wiring corresponding to the first group of piezoelectric actuators are insulated from each other, and the positive-polarity wiring and the negative-polarity wiring corresponding to the second group of piezoelectric actuators are insulated from each other;
the positive-polarity lead wire and the negative-polarity lead wire corresponding to the first group of piezoelectric actuators are insulated from each other; and the positive-polarity lead wire and the negative-polarity lead wire corresponding to the second group of piezoelectric actuators are insulated from each other.

In some embodiments, in the haptic feedback component provided by the present disclosure, in the first solid region, the second solid region, the third solid region and the fourth solid region, the piezoelectric actuators correspond one-to-one with the connection pad groups;
the positive-polarity connection pads corresponding to the piezoelectric actuators in a same row in the first solid region and the second solid region are arranged in a same row and arranged along the second direction, and the negative-polarity connection pads corresponding to the piezoelectric actuators in the same row in the first solid region and the second solid region are arranged in a same row and arranged along the second direction;
the positive-polarity connection pads corresponding to the piezoelectric actuators in a same column in the third solid region and the fourth solid region are arranged in a same column and arranged along the first direction, and the negative-polarity connection pads corresponding to the piezoelectric actuators in the same column in the third solid region and the fourth solid region are arranged in a same column and arranged along the first direction.

In some embodiments, in the haptic feedback component provided by the present disclosure, the third solid region is divided into a first sub-solid region and a second sub-solid region along the first direction, and the fourth solid region is divided into a third sub-solid region and a fourth sub-solid region along the first direction, the first sub-solid region and the third sub-solid region are proximate to the second solid region, and the second sub-solid region and the fourth sub-solid region are proximate to the first solid region;
the second group of piezoelectric actuators includes: a first sub-group of piezoelectric actuators located in the first sub-solid region and the third sub-solid region, and a second sub-group of piezoelectric actuators located in the second sub-solid region and the fourth sub-solid region;
the positive-polarity wiring and the negative-polarity wiring corresponding to the first sub-group of piezoelectric actuators and the positive-polarity wiring and the negative-polarity wiring corresponding to the second sub-group of piezoelectric actuators are different; and the positive-polarity lead wire and the negative-polarity lead wire corresponding to the first sub-group of piezoelectric actuators and the positive-polarity lead wire and the negative-polarity lead wire corresponding to the second sub-group of piezoelectric actuators are different.

In some embodiments, in the haptic feedback component provided by the present disclosure, in the first sub-solid region, the positive-polarity connection pads corresponding to the piezoelectric actuators in different columns are aligned along the second direction;
in the third sub-solid region, the positive-polarity connection pads corresponding to the piezoelectric actuators in different columns are aligned along the second direction;
in the first sub-solid region, the negative-polarity connection pads corresponding to the piezoelectric actuators in different columns are aligned along the second direction;
in the third sub-solid region, the negative-polarity connection pads corresponding to the piezoelectric actuators in different columns are aligned along the second direction;
in the first sub-solid region, the positive-polarity connection pads and the negative-polarity connection pads in a same column are alternately arranged along the first direction;
in the third sub-solid region, the positive-polarity connection pads and the negative-polarity connection pads in a same column are alternately arranged along the first direction.

In some embodiments, in the haptic feedback component provided by the present disclosure, the plurality of piezoelectric actuators in the first sub-solid region are arranged in a same column and arranged in sequence along the first direction, the negative-polarity connection pads of the piezoelectric actuators in the first sub-solid region are proximate to an outer edge of the first sub-solid region and arranged along the first direction, and the positive-polarity connection pads of the piezoelectric actuators in the first sub-solid region are proximate to an inner edge of the first sub-solid region and arranged along the first direction;
the plurality of piezoelectric actuators in the third sub-solid region are arranged in a same column and arranged in sequence along the first direction, the negative-polarity connection pads of the piezoelectric actuators in the third sub-solid region are proximate to an outer edge of the third sub-solid region and arranged along the first direction, and the positive-polarity connection pads of the piezoelectric actuators in the third sub-solid region are proximate to an inner edge of the third sub-solid region and arranged along the first direction.

In some embodiments, in the haptic feedback component provided by the present disclosure, the positive-polarity connection pads located in the second sub-solid region are arranged in a same column and are arranged sequentially along the first direction;
the negative-polarity connection pads located in the second sub-solid region are arranged in a same column and are arranged sequentially along the first direction;
the positive-polarity connection pads and the negative-polarity connection pads are arranged in different columns, and the positive-polarity connection pads and the negative-polarity connection pads are alternately arranged along the first direction.

In some embodiments, in the haptic feedback component provided by the present disclosure, the positive-polarity connection pads located in the fourth sub-solid region are arranged in a same column and are arranged sequentially along the first direction;
the negative-polarity connection pads located in the fourth sub-solid region are arranged in a same column and are arranged sequentially along the first direction;
the positive-polarity connection pads and the negative-polarity connection pads are arranged in different columns, and the positive-polarity connection pads and the negative-polarity connection pads are alternately arranged along the first direction.

In some embodiments, in the haptic feedback component provided by the present disclosure, the solid region further includes a fifth solid region, the fifth solid region is located on a side of the first solid region away from the second solid region, and the at least one input pad group is located in the fifth solid region.

In some embodiments, in the haptic feedback component provided by the present disclosure, the fifth solid region is located at an edge of the first solid region and proximate to the third solid region; or
the fifth solid region is located at an edge of the first solid region and proximate to the fourth solid region; or
the fifth solid region is located in a middle region of the first solid region.

In some embodiments, in the haptic feedback component provided by the present disclosure, the at least one input pad group includes: a first input pad group corresponding to the first group of piezoelectric actuators, a second input pad group corresponding to the first sub-group of piezoelectric actuators, and a third input pad group corresponding to the second sub-group of piezoelectric actuators.

In some embodiments, in the haptic feedback component provided by the present disclosure, the at least one input pad group includes:
a first input pad group located in the first solid region and corresponding to the piezoelectric actuators in the first solid region;
a second input pad group located in the second solid region and corresponding to the piezoelectric actuators in the second solid region;
a third input pad group located in the first sub-solid region and corresponding to the piezoelectric actuators in the first sub-solid region;
a fourth input pad group located in the third sub-solid region and corresponding to the piezoelectric actuators in the third sub-solid region;
a fifth input pad group located in the second sub-solid region and corresponding to the piezoelectric actuators in the second sub-solid region; and
a sixth input pad group located in the fourth sub-solid region and corresponding to the piezoelectric actuators in the fourth sub-solid region.

In some embodiments, in the haptic feedback component provided by the present disclosure, the first input pad group is located at one end of the first solid region, and the second input pad group is located at one end of the second solid region;
the third input pad group is located at one end of the first sub-solid region, the fourth input pad group is located at one end of the third sub-solid region, and the third input pad group and the fourth input pad group are proximate to the second solid region;
the fifth input pad group is located at one end of the second sub-solid region, the sixth input pad group is located at one end of the fourth sub-solid region, and the fifth input pad group and the sixth input pad group are proximate to the first solid region.

In some embodiments, in the haptic feedback component provided by the present disclosure, a shape of the piezoelectric actuator includes a rectangle or a circle; and
a structure of the piezoelectric actuator is a piezoelectric film or a piezoelectric ceramic block.

Embodiments of the present disclosure further provide a haptic feedback display device, including:
a cover plate;
a display module, arranged on a non-touch surface of the cover plate;
a haptic feedback component, arranged on the non-touch surface of the cover plate, and the haptic feedback component is the haptic feedback component provided in the above embodiments.

In some embodiments, in the haptic feedback display device provided by the present disclosure, the cover plate includes a central region and a peripheral region surrounding the central region;
the display module is arranged in the central region of the cover plate;
a hollow region of the haptic feedback component corresponds to the central region of the cover plate; and
a solid region of the haptic feedback component corresponds to the peripheral region of the cover plate.

### BRIEF DESCRIPTION OF FIGURES

FIG. 1 is a top view schematic diagram of a flexible circuit board in a haptic feedback component provided by embodiments of the present disclosure.

FIG. 2 is a schematic cross-sectional view along the CC′ direction in FIG. 1.

FIG. 3 is a top view schematic diagram of a piezoelectric actuator in a haptic feedback component provided by embodiments of the present disclosure.

FIG. 4 is a schematic diagram of a partition of the piezoelectric actuators connected to the flexible circuit board in FIG. 1.

FIG. 5 is a schematic diagram of the wirings of a portion of the flexible circuit board in FIG. 1.

FIG. 6 is a schematic diagram of the wirings of another portion of the flexible circuit board in FIG. 1.

FIG. 7 is a schematic diagram of the wirings of another portion of the flexible circuit board in FIG. 1.

FIG. 8 is an enlarged schematic diagram of the fifth solid region B5 and the surrounding region in FIG. 1.

FIG. 9 is a top view schematic diagram of a flexible circuit board in another haptic feedback component provided by embodiments of the present disclosure.

FIG. 10 is a schematic diagram of a partition of the piezoelectric actuators connected to the flexible circuit board in FIG. 9.

FIG. 11 only shows the structures of the wirings and the lead wires in the first sub-solid region and the third sub-solid region in FIG. 9.

FIG. 12 is a top view schematic diagram a flexible circuit board in another haptic feedback component provided by embodiments of the present disclosure.

FIG. 13 only shows the structures of the wirings and the lead wires in the first solid region and the second solid region in FIG. 12.

FIG. 14 only shows the structures of the wirings and the lead wires in the first sub-solid region and the third sub-solid region in FIG. 12.

FIG. 15 only shows the structures of the wirings and the lead wires in the second sub-solid region and the fourth sub-solid region in FIG. 12.

FIG. 16 is an enlarged schematic diagram of the fifth solid region and the surrounding region in FIG. 12.

FIG. 17 is a top view schematic diagram of a flexible circuit board in another haptic feedback component provided by embodiments of the present disclosure.

FIG. 18 is a top view schematic diagram of a flexible circuit board in another haptic feedback component provided by embodiments of the present disclosure.

FIG. 19 is a top view schematic diagram of a flexible circuit board in another haptic feedback component provided by embodiments of the present disclosure.

FIG. 20 is a structural schematic diagram of the first solid region in FIG. 19.

FIG. 21 is a structural schematic diagram of the second solid region in FIG. 19.

FIG. 22 is a structural schematic diagram of the first sub-solid region in FIG. 19.

FIG. 23 is a structural schematic diagram of the second sub-solid region in FIG. 19.

FIG. 24 is a structural schematic diagram of the third sub-solid region in FIG. 19.

FIG. 25 is a structural schematic diagram of the fourth sub-solid region in FIG. 19.

FIG. 26 is a schematic top view of a flexible circuit board in another haptic feedback component provided by embodiments of the present disclosure.

FIG. 27 is a structural schematic diagram of a haptic feedback display device provided by embodiments of the present disclosure.

### DETAILED DESCRIPTION

In order to make the purpose, technical solutions and advantages of embodiments of the present disclosure more clear, the technical solutions of the embodiments of the present disclosure will be clearly and completely described below in conjunction with the drawings of embodiments of the present disclosure. Obviously, the described embodiments are some, but not all, of the embodiments of the present disclosure. And the embodiments and features in the embodiments of the present disclosure may be combined with each other without conflict. Based on the described embodiments of the present disclosure, all other embodiments obtained by those of ordinary skill in the art without creative efforts fall within the scope of the present disclosure.

Unless otherwise defined, technical terms or scientific terms used in this disclosure shall have the usual meaning understood by a person with ordinary skill in the art to which this disclosure belongs. Words such as “including” or “comprising” refer to the components or objects that appear before the word, including those listed after the word and their equivalents, without excluding other components or objects. Words such as “connected” or “connecting” are not limited to physical or mechanical connections, but may include electrical connections, whether direct or indirect. Words such as “inside”, “outside”, “up”, “down” are only used to express relative positional relationships. When the absolute position of the described object is changed, the relative positional relationship may also be changed accordingly.

It should be noted that the sizes and shapes of the figures in the drawings do not reflect true proportions and are only intended to illustrate the present disclosure. And, the same or similar reference numbers throughout represent the same or similar components or elements having the same or similar functions.

The multi-modal fusion of vision, hearing and touch is of great significance and value in enhancing the safety and effectiveness of operations and enriching the user experience. At present, the visual and auditory presentation technologies are relatively mature and rich, but the haptic feedback is not rich and realistic enough. At present, the fields of mobile phones and wearable devices mainly generate vibration feedback through the low-frequency vibration of ERM and LRA, and the effect is relatively simple and single, far from meeting the expectations of users. However, by using piezoelectric transducers, auditory reminders can be generated through the action of sound excitation signals during human-computer interaction; low-frequency vibration signals can be used to generate vibration haptic feedback effects; the excitation signal of the ultrasonic segment can produce a film squeeze effect to change the surface friction coefficient, and waveform modulation can be used to generate virtual surface haptic feedback effects similar to texture and jamming.

At present, the surface haptic feedback display structure generally arranges piezoelectric actuators in the peripheral region of the cover plate. The piezoelectric actuators are generally connected to an external driving circuit through wiring on the cover plate. The piezoelectric actuators are stimulated by the external driving circuit to vibrate and drive the cover plate to resonate to achieve haptic feedback. Since the number of piezoelectric actuators is generally large, the conventional wire connection method of wiring on the cover plate will be more, and in order to meet the maximum current requirements, thicker diameter wiring must be selected, and the display assembly requirements generally do not have much space to place so many wiring. At the same time, since the piezoelectric actuator itself will drive vibration, too many wiring connections will generate unpredictable noise with the vibration, thereby affecting the haptic feedback experience of the product.

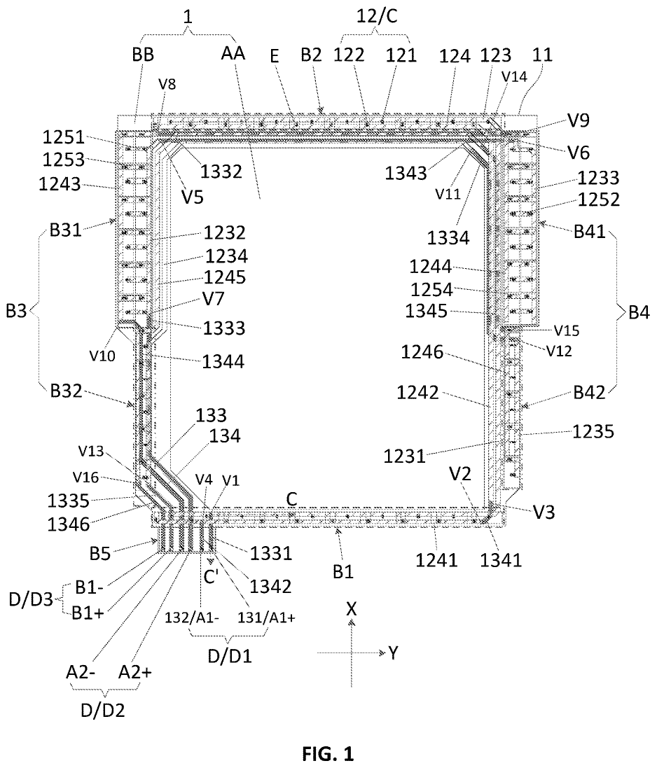

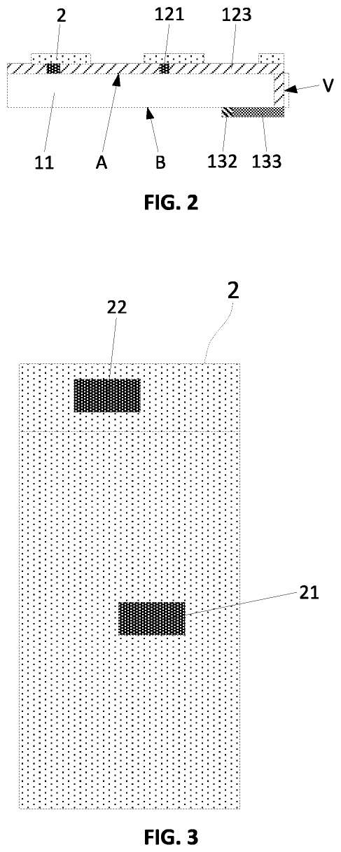

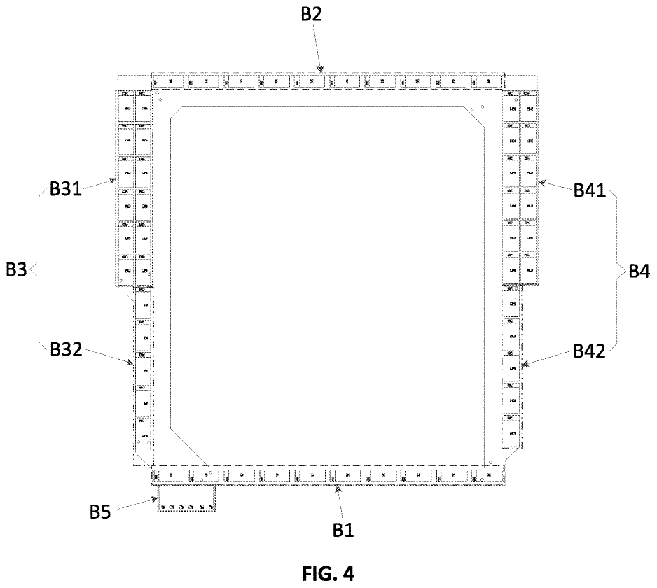

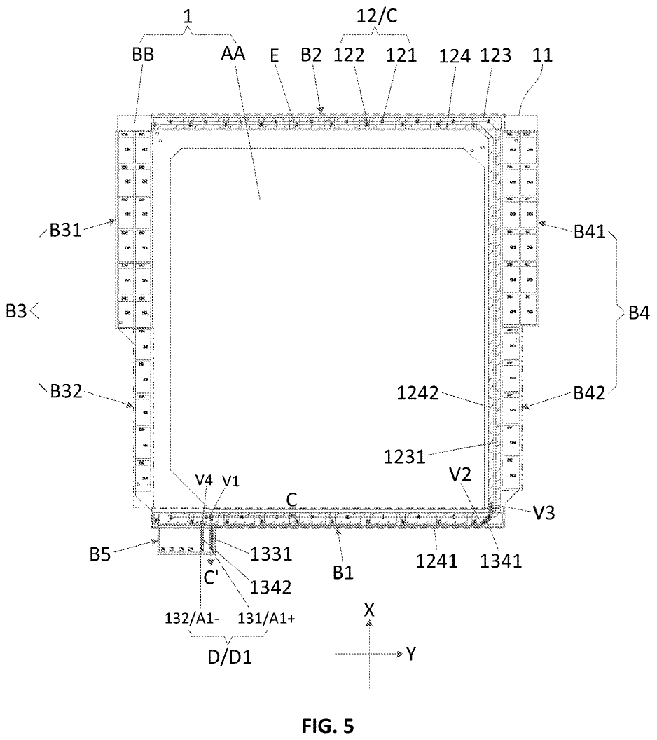

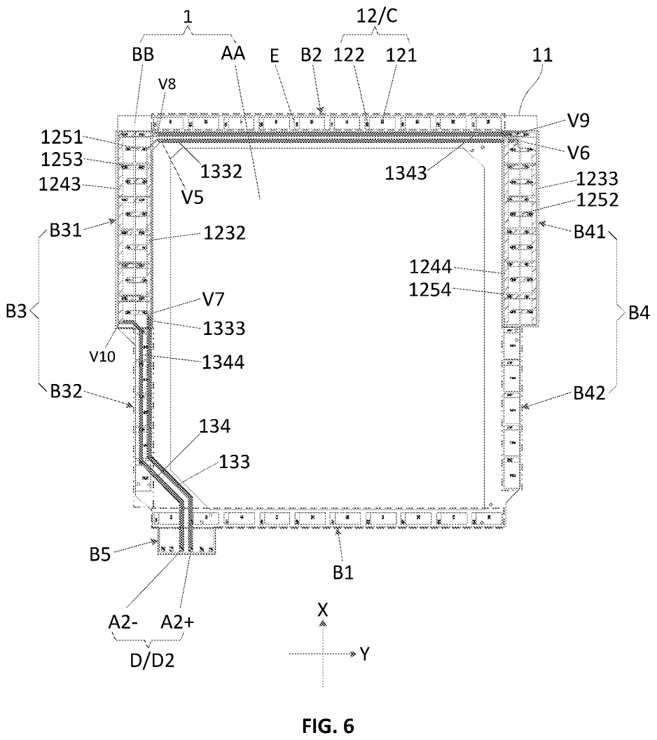

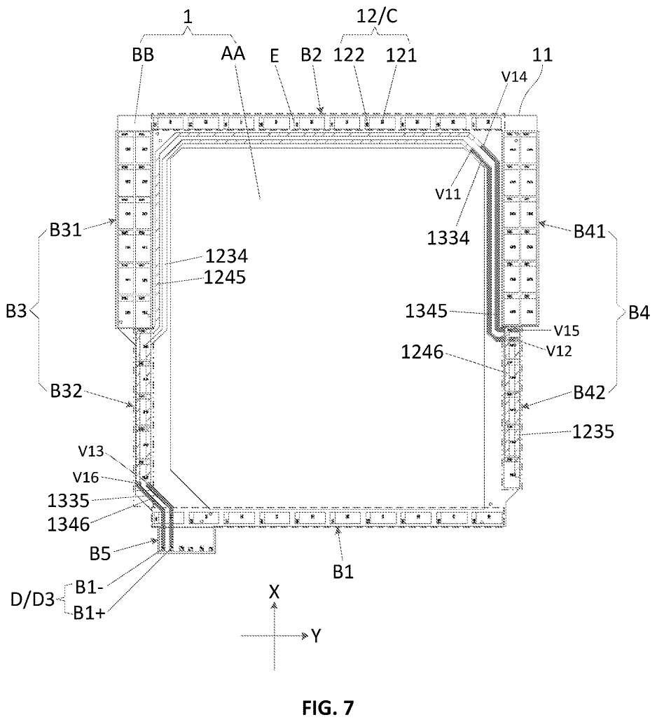

In order to solve the problem that the frame of the existing surface haptic feedback display structure does not have a lot of space to place the connection wiring of the piezoelectric actuator and that too many connection wirings of the piezoelectric actuator will generate noise with vibration, embodiments of the present disclosure provide a haptic feedback component, as shown in FIGS. 1 to 6. FIG. 1 is a top view schematic diagram of a flexible circuit board in a haptic feedback component provided by embodiments of the present disclosure; FIG. 2 is a schematic cross-sectional view along the CC′ direction in FIG. 1; FIG. 3 is a top view schematic diagram of a piezoelectric actuator in a haptic feedback component provided by embodiments of the present disclosure; FIG. 4 is a schematic diagram of a partition of the piezoelectric actuators connected to the flexible circuit board in FIG. 1; FIG. 5 is a schematic diagram of the wirings of a portion of the flexible circuit board in FIG. 1; FIG. 6 is a schematic diagram of the wirings of another portion of the flexible circuit board in FIG. 1; FIG. 7 is a schematic diagram of the wirings of another portion of the flexible circuit board in FIG. 1. The haptic feedback component includes:
a flexible circuit board 1 (FPC), including: a flexible substrate 11, a first metal layer 12 arranged on a first surface A of the flexible substrate 11, and a second metal layer 13 arranged on a second surface B of the flexible substrate 11; where the first surface A and the second surface B are arranged opposite to each other along a thickness direction of the flexible substrate 11; the first metal layer 12 includes a plurality of connection pad groups C, and the second metal layer 13 includes at least one input pad group D;
a plurality of piezoelectric actuators 2, arranged on a side of the first metal layer 12 facing away from the flexible substrate 11, where each of the plurality of piezoelectric actuators 2 is electrically connected to one of the plurality of connection pad groups C; the plurality of piezoelectric actuators 2 are divided into at least one group, the piezoelectric actuators 2 in a same group are electrically connected to a same input pad group D, and the piezoelectric actuators 2 in different groups are electrically connected to different input pad groups D; the plurality of piezoelectric actuators 2 are configured to generate haptic feedback in response to a drive signal input by the at least one input pad group D.

In the haptic feedback component provided by embodiments of the present disclosure, different groups of piezoelectric actuators are connected to corresponding input pad groups by means of FPC, and the input pad groups can be connected to an external PCB. Since the FPC can be wired on both sides, when the haptic feedback component of the present disclosure is integrated with a display or touch substrate, the space occupied by the wiring connecting the piezoelectric actuators in the frame region of the substrate can be reduced, thereby achieving a narrow frame. And, by reasonably arranging the wiring of the piezoelectric actuator connected to the PCB, the noise generated by the wiring as the piezoelectric actuator vibrates can also be reduced.

It should be noted that, for the sake of schematic illustration, FIGS. 1 and 5 to 7 illustrate the first metal layer 12 on the first surface A of the flexible substrate 11 and the second metal layer 13 on the second surface B in the same plane as an example. Of course, the actual structure is that the first metal layer 12 and the second metal layer 13 shown in FIG. 2 are arranged on opposite sides of the flexible substrate 11.

It should be noted that the dotted frame E in FIG. 1 and FIG. 4 to FIG. 7 respectively demarcates the welding position corresponding to each piezoelectric actuator 2, that is, the dotted frame E is the region occupied by the piezoelectric actuator 2 on the flexible circuit board 1 shown in FIG. 3.

In some embodiments, in the above-mentioned haptic feedback component provided by embodiments of the present disclosure, the material of the flexible substrate 11 includes but is not limited to PI (polyimide), PMMA (polymethyl methacrylate), PC (polycarbonate), PET (Polyethylene terephthalate), PC/PMMA composite materials, and organic-inorganic composite materials.

In some embodiments, in the above-mentioned haptic feedback component provided by the embodiments of the present disclosure, as shown in FIG. 1 and FIG. 3, the piezoelectric actuator 2 has a positive-polarity lead-out structure 21 and a negative-polarity lead-out structure 22 on one side facing the first metal layer 12, and each connection pad group C includes a positive-polarity connection pad 121 and a negative-polarity connection pad 122, the positive-polarity lead-out structure 21 is electrically connected to the positive-polarity connection pad 121, and the negative-polarity lead-out structure 22 is electrically connected to the negative-polarity connection pad 122. For example, the positive-polarity lead-out structure 21 of the piezoelectric actuator 2 shown in FIG. 3 is welded to the positive-polarity connection pad 121 in the dotted frame E, and the negative-polarity lead-out structure 22 is welded to the negative-polarity connection pad 122 in the dotted frame E.

Each input pad group D includes a positive-polarity input pad 131, the first metal layer 12 further includes a positive-polarity wiring 123, and the second metal layer 13 further includes a positive-polarity lead wire 133.

Each positive-polarity connection pad 121 electrically connected to the piezoelectric actuator 2 of the same group is electrically connected to the corresponding positive-polarity input pad 131 through at least one positive-polarity wiring 123 and at least one positive-polarity lead wire 133.

In some embodiments, in the above-mentioned haptic feedback component provided by embodiments of the present disclosure, as shown in FIGS. 1 and 3, each input pad group D further includes a negative-polarity input pad 132, the first metal layer 12 further includes a negative-polarity wiring 124, and the second metal layer 13 further includes a negative-polarity lead wire 134; each negative-polarity connection pad 122 electrically connected to the piezoelectric actuator 2 of the same group is electrically connected to the corresponding negative-polarity input pad 132 through at least one negative-polarity wiring 124 and at least one negative-polarity lead wire 134.

In this way, the positive-polarity lead-out structure 21 of the piezoelectric actuator 2 is connected to the external PCB through the positive-polarity connection pad 121 on the first surface A of the FPC, the positive-polarity lead wire 123 on the first surface A of the FPC, the positive-polarity lead wire 133 on the second surface B, and the positive-polarity input pad 131 on the second surface B. The PCB inputs a positive-polarity driving signal to the positive-polarity lead-out structure 21 of the piezoelectric actuator 2 through the positive-polarity input pad 131, the positive-polarity lead wire 133, the positive-polarity wiring 123, and the positive-polarity connection pad 121. The negative-polarity lead-out structure 22 of the piezoelectric actuator 2 is connected to the external PCB through the negative-polarity connection pad 122 on the first surface A of the FPC, the negative-polarity wiring 124 on the first surface A of the FPC, the negative-polarity lead wire 134 on the second surface B, and the negative-polarity input pad 132 on the second surface B. The PCB inputs a negative-polarity driving signal to the negative-polarity lead-out structure 22 of the piezoelectric actuator 2 through the negative-polarity input pad 132, the negative-polarity lead wire 134, the negative-polarity wiring 124 and the negative-polarity connection pad 122. In this way, the piezoelectric actuator 2 vibrates under the excitation of the driving signal to generate haptic feedback.

In some embodiments, in the above-mentioned haptic feedback component provided by embodiments of the present disclosure, as shown in FIG. 1 and FIG. 4 to FIG. 7, the flexible circuit board 1 includes a hollow region AA and a solid region BB surrounding the hollow region AA, and a plurality of connection pad groups C are arranged around the hollow region AA.

The solid region BB includes a first solid region B1 and a second solid region B2 arranged on opposite sides of the hollow region AA in a first direction X, and the solid region BB further includes a third solid region B3 and a fourth solid region B4 arranged on opposite sides of the hollow region AA in a second direction Y, and the first direction X is perpendicular to the second direction Y.

The plurality of piezoelectric actuators 2 include: a first group of piezoelectric actuators located in the first solid region B1 and the second solid region B2, and a second group of piezoelectric actuators located in the third solid region B3 and the fourth solid region B4.

In the first solid region B1 and the second solid region B2, the multiple piezoelectric actuators 2 are located in at least one row and the multiple piezoelectric actuators 2 in each row are arranged in sequence along the second direction Y. In the third solid region B3 and the fourth solid region B4, the multiple piezoelectric actuators 2 are located in at least one column, and the multiple piezoelectric actuators 2 in each column are arranged in sequence along the first direction X.

In some embodiments, as shown in FIG. 1 and FIG. 4 to FIG. 7, embodiments of the present disclosure take the example that the first solid region B1 and the second solid region B2 each include only one row of piezoelectric actuators 2, but is certainly not limited thereto.

In some embodiments, in the above-mentioned haptic feedback component provided by embodiments of the present disclosure, as shown in FIGS. 1 and 4, in the first solid region B1, the second solid region B2, the third solid region B3 and the fourth solid region B4, each piezoelectric actuator 2 corresponds to the connection pad group C one by one. In the first solid region B1 and the second solid region B2, the positive-polarity connection pads 121 corresponding to the piezoelectric actuators 2 in the same row are located in the same row and arranged along the second direction Y. And, in the first solid region B1 and the second solid region B2, the negative-polarity connection pads 122 corresponding to the piezoelectric actuators 2 in the same row are located in the same row and arranged along the second direction Y. In the third solid region B3 and the fourth solid region B4, the positive-polarity connection pads 121 corresponding to the piezoelectric actuators 2 in the same column are located in the same column and arranged along the first direction X. And, in the third solid region B3 and the fourth solid region B4, the negative-polarity connection pads 122 corresponding to the piezoelectric actuators 2 in the same column are located in the same column and arranged along the first direction X. In this way, it can be ensured that piezoelectric actuators 2 are provided at various positions of the first solid region B1 and the second solid region B2. When the haptic feedback component is integrated in the peripheral region of the cover plate, the haptic feedback effect is improved, and the piezoelectric actuators 2 are provided in the same row to achieve a narrow frame.

In some embodiments, in the above-mentioned haptic feedback component provided by embodiments of the present disclosure, as shown in FIG. 1 and FIG. 4, all positive-polarity connection pads 121 located in the first solid region B1 are arranged in the same row and arranged in sequence along the second direction Y, all negative-polarity connection pads 122 located in the first solid region B1 are arranged in the same row and arranged in sequence along the second direction Y, the positive-polarity connection pads 121 in the first solid region B1 and the negative-polarity connection pads 122 in the first solid region B1 are arranged in different rows, and the positive-polarity connection pads 121 in the first solid region B1 and the negative-polarity connection pads 122 in the first solid region B1 are alternately arranged along the second direction Y. This is conducive to the electrical connection of the positive-polarity wiring 123 and the positive-polarity connection pad 121, and the electrical connection of the negative-polarity wiring 124 and the negative-polarity connection pad 122.

In some embodiments, in the above-mentioned haptic feedback component provided by embodiments of the present disclosure, as shown in FIG. 1 and FIG. 4, all positive-polarity connection pads 121 in the second solid region B2 are arranged in the same row and arranged in sequence along the second direction Y, all negative-polarity connection pads 122 in the second solid region B2 are arranged in the same row and arranged in sequence along the second direction Y, the positive-polarity connection pads 121 in the second solid region B2 and the negative-polarity connection pads 122 in the second solid region B2 are in different rows, and the positive-polarity connection pads 121 in the second solid region B2 and the negative-polarity connection pads 122 in the second solid region B2 are alternately arranged along the second direction Y. This is conducive to the electrical connection between the positive-polarity wiring 123 and the positive-polarity connection pad 121, and the electrical connection between the negative-polarity wiring 124 and the negative-polarity connection pad 122.

In some embodiments, in the above-mentioned haptic feedback component provided by embodiments of the present disclosure, as shown in FIG. 1, the solid region BB further includes a fifth solid region B5, and the fifth solid region B5 is arranged on the side of the first solid region B1 away from the second solid region B2, and the input pad groups D can be located in the fifth solid region B5.

In some embodiments, in the haptic feedback component provided by embodiments of the present disclosure, as shown in FIG. 1, the fifth solid region B5 can be located at the edge of the first solid region B1 and proximate to the third solid region B3.

In this way, by dividing the annular solid region BB into two regions, some solid regions can be controlled to be driven at high frequencies and other solid regions can be driven at low frequencies according to the haptic feedback effects required by different regions. For example, the first solid region B1 and the second solid region B2 can be driven at high frequencies, and the third solid region B3 and the fourth solid region B4 can be driven at low frequencies, thereby achieving different haptic feedback effects.

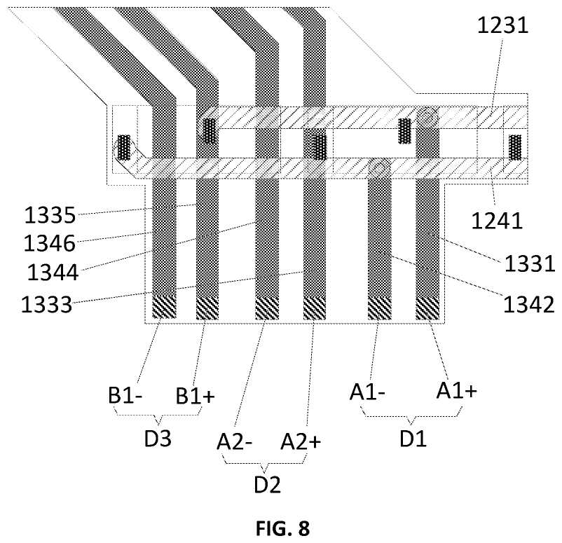

In some embodiments, in the above-mentioned haptic feedback component provided by the embodiments of the present disclosure, as shown in FIG. 1 and FIG. 8, FIG. 8 is an enlarged schematic diagram of the fifth solid region B5 and the surrounding region in FIG. 1, the input pad groups D include a first input pad group D1 corresponding to the first group of piezoelectric actuators, and the first input pad group D1 can be located at the corner of the fifth solid region B5 proximate to the fourth solid region B4, and the first input pad group D1 includes a first positive-polarity input pad A1+ and a first negative-polarity input pad A1− arranged along the second direction Y, and the first positive-polarity input pad A1+ can be proximate to the fourth solid region B4. In this way, all positive-polarity connection pads 121 of the first solid region B1 and the second solid region B2 can be electrically connected to the first positive-polarity input pad A1+ through at least one positive-polarity wiring 123 and at least one positive-polarity lead wire 133, and all negative-polarity connection pads 122 of the first solid region B1 and the second solid region B2 can be electrically connected to the first negative-polarity input pad A1− through at least one negative-polarity wiring 124 and at least one negative-polarity lead wire 134.

In some embodiments, in the above-mentioned haptic feedback component provided by embodiments of the present disclosure, as shown in FIG. 1 and FIG. 5, FIG. 5 only shows the wiring and lead-out structure corresponding to the first solid region B1 and the second solid region B2 in FIG. 1, the positive-polarity wiring 123 corresponding to the first group of piezoelectric actuators and the positive-polarity lead wire 133 corresponding to the first group of piezoelectric actuators are electrically connected by means of via hole penetrating through the flexible substrate 11. For example, the positive-polarity wiring 123 corresponding to the first group of piezoelectric actuators is the first positive-polarity wiring 1231 that is sequentially routed along the first solid region B1, the fourth solid region B4, and the second solid region B2. All positive-polarity connection pads 121 in the first solid region B1 and a second solid region B2 are electrically connected to the first positive-polarity wiring 1231. For example, the positive-polarity lead wire 133 corresponding to the first group of piezoelectric actuators is the first positive-polarity lead wire 1331 located in the fifth solid region B5 and extending along the first direction X, one end of the first positive-polarity lead wire 1331 is electrically connected to the first positive-polarity input pad A1+, and the other end of the first positive-polarity lead wire 1331 extends to the first solid region B1 and is electrically connected to the first positive-polarity wiring 1231 by means of a via hole (V1) penetrating through the flexible substrate 11.

In some embodiments, in the above-mentioned haptic feedback component provided by embodiments of the present disclosure, as shown in FIG. 1 and FIG. 5, the negative-polarity wiring 124 corresponding to the first group of piezoelectric actuators and the negative-polarity lead wire 134 corresponding to the first group of piezoelectric actuators are electrically connected by means of a via hole penetrating through the flexible substrate 11. For example, the negative-polarity wirings 124 corresponding to the first group of piezoelectric actuators include: a first negative-polarity wiring 1241 in the first solid region B1 and extending along the second direction Y, and a second negative-polarity wiring 1242 along the fourth solid region B4 and the second solid region B2. For example, the negative-polarity lead wires 134 corresponding to the first group of piezoelectric actuators include: a first negative-polarity lead wire 1341 intersecting with the orthographic projection of the first positive-polarity wiring 1231 at the corner of the first solid region B1 and the fourth solid region B4, and a second negative-polarity lead wire 1342 arranged on one side of the first positive-polarity lead wire 1331 proximate to the third solid region B3 and extending along the first direction X. All negative-polarity connection pads 122 in the first solid region B1 are electrically connected to the first negative-polarity wiring 1241, and all negative-polarity connection pads 122 in the second solid region B2 are electrically connected to the second negative-polarity wiring 1242; one end of the first negative-polarity wiring 1241 proximate to the fourth solid region B4 is electrically connected to one end of the first negative-polarity lead wire 1341 by means of a via hole (V2) penetrating through the flexible substrate 11, and the other end of the first negative-polarity lead wire 1341 is electrically connected to the second negative-polarity wiring 1242 by means of a via hole (V3) penetrating through the flexible substrate 11. One end of the second negative-polarity lead wire 1342 is electrically connected to the first negative-polarity input pad A1−, and the other end of the second negative-polarity lead wire 1342 extends to the first solid region B1 and is electrically connected to the first negative-polarity wiring 1241 by means of a via hole (V4) penetrating through the flexible substrate 11.

In some embodiments, as shown in FIGS. 1 and 5, each positive-polarity wiring (1231) corresponding to the first group of piezoelectric actuators and each negative-polarity wiring (1241, 1242) corresponding to the first group of piezoelectric actuators are insulated from each other, and each positive-polarity lead wire (1331) corresponding to the first group of piezoelectric actuators and each negative-polarity lead wire (1341, 1342) corresponding to the first group of piezoelectric actuators are insulated from each other.

In this way, the positive-polarity lead-out structures 21 of all the piezoelectric actuators 2 in the first solid region B1 and the second solid region B2 are connected in parallel, and the negative-polarity lead-out structures 22 of all the piezoelectric actuators 2 in the first solid region B1 and the second solid region B2 are connected in parallel. All the piezoelectric actuators 2 in the first solid region B1 and the second solid region B2 are driven together, which can improve the haptic feedback effect. The first solid region B1 and the second solid region B2 are controlled to be high-frequency driven or low-frequency driven according to the haptic feedback demand. For example, a ground voltage signal is applied to the first negative-polarity input pad A1− through the PCB, and the ground voltage signal is transmitted to the negative-polarity lead-out structure 22 of each piezoelectric actuator 2 through the first negative-polarity input pad A1−, the first negative-polarity wiring 1241, the first negative-polarity lead wire 1341, the second negative-polarity wiring 1242 and the negative-polarity connection pad 122. And, an AC voltage signal is applied to the first positive-polarity input pad A1+, and the AC voltage signal is transmitted to the positive-polarity lead-out structure 21 of each piezoelectric actuator 2 through the first positive-polarity input pad A1+, the first positive-polarity lead wire 1331, the first positive-polarity wiring 1231 and the positive-polarity connection pad 121, so that an alternating electric field can be formed between the positive-polarity lead-out structure 21 of the piezoelectric actuator 2 and the negative-polarity lead-out structure 22 of the piezoelectric actuator 2, and under the action of the alternating electric field, the piezoelectric actuator 2 generates vibration to achieve haptic feedback.

In some embodiments, in the above-mentioned haptic feedback component provided by embodiments of the present disclosure, as shown in FIG. 1 and FIG. 4 to FIG. 7, the third solid region B3 is divided into a first sub-solid region B31 and a second sub-solid region B32 along the first direction X, and the fourth solid region B4 is divided into a third sub-solid region B41 and a fourth sub-solid region B42 along the first direction X, the first sub-solid region B31 and the third sub-solid region B41 are proximate to the second solid region B2, and the second sub-solid region B32 and the fourth sub-solid region B42 are proximate to the first solid region B1.

The second group of piezoelectric actuators includes: a first sub-group of piezoelectric actuators in the first sub-solid region B31 and the third sub-solid region B41, and a second sub-group of piezoelectric actuators B42 in the second sub-solid region B32 and the fourth sub-solid region.

The positive-polarity wirings 123 and the negative-polarity wirings 124 corresponding to the first sub-group of piezoelectric actuators are different from the positive-polarity wirings 123 and the negative-polarity wirings 124 corresponding to the second sub-group of piezoelectric actuators, and the positive-polarity lead wires 133 and the negative-polarity lead wires 134 corresponding to the first sub-group of piezoelectric actuators are different from the positive-polarity lead wires 133 and the negative-polarity lead wires 134 corresponding to the second sub-group of piezoelectric actuators.

In this way, by further dividing the annular solid region BB into three regions, some solid regions can be controlled to be driven at high frequencies and other solid regions can be driven at low frequencies according to the haptic feedback effects required by different regions. For example, the first solid region B1 and the second solid region B2 can be driven at high frequencies, and the first sub-solid region B31, the second sub-solid region B32, the third sub-solid region B41 and the fourth sub-solid region B42 can be driven at low frequencies, thereby achieving different haptic feedback effects.

In some embodiments, in the above-mentioned haptic feedback component provided by embodiments of the present disclosure, as shown in FIG. 1 and FIG. 4, the first sub-solid region B31 and the third sub-solid region B41 both include multiple piezoelectric actuators 2. The multiple piezoelectric actuators 2 in the first sub-solid region B31 are arranged in different columns and the multiple piezoelectric actuators 2 in each column are arranged in sequence along the first direction X. The multiple piezoelectric actuators 2 in the third sub-solid region B41 are arranged in different columns and the multiple piezoelectric actuators 2 in each column are arranged in sequence along the first direction X. For example, in some embodiments, the piezoelectric actuators 2 in the first sub-solid region B31 and the third sub-solid region B41 are arranged in two columns, which can increase the number of piezoelectric actuators 2 in the first sub-solid region B31 and the third sub-solid region B41, and improve the haptic feedback effect.

In some embodiments, in the above-mentioned haptic feedback component provided by embodiments of the present disclosure, as shown in FIG. 1 and FIG. 4, the positive-polarity connection pads 121 corresponding to different columns of piezoelectric actuators 2 in the first sub-solid region B31 are aligned along the second direction Y, and the negative-polarity connection pads 122 corresponding to different columns of piezoelectric actuators 2 in the first sub-solid region B31 are aligned along the second direction Y, and the positive-polarity connection pads 121 and the negative-polarity connection pads 122 in the same column in the first sub-solid region B31 are alternately arranged along the first direction X. This is conducive to using the same positive-polarity wiring 123 to electrically connect all the positive-polarity connection pads 121 in the first sub-solid region B31, and using the same negative-polarity wiring 124 to electrically connect all the negative-polarity connection pads 122 in the first sub-solid region B31, so as to achieve driving all the piezoelectric actuators 2 of the first sub-solid region B31 together.

In some embodiments, in the above-mentioned haptic feedback component provided by embodiments of the present disclosure, as shown in FIG. 1 and FIG. 4, the positive-polarity connection pads 121 corresponding to different columns of piezoelectric actuators 2 in the third sub-solid region B41 are aligned along the second direction Y, and the negative-polarity connection pads 122 corresponding to different columns of piezoelectric actuators 2 in the third sub-solid region B41 are aligned along the second direction Y, and the positive-polarity connection pads 121 and the negative-polarity connection pads 122 in the same column in the third sub-solid region B41 are alternately arranged along the first direction X. This is conducive to electrically connecting all the positive-polarity connection pads 121 of the third sub-solid region B41 using the same positive-polarity wiring 123, and electrically connecting all the negative-polarity connection pads 122 of the third sub-solid region B41 using the same negative-polarity wiring 124, so as to realize driving all the piezoelectric actuators 2 of the third sub-solid region B41 together.

In some embodiments, in the above-mentioned haptic feedback component provided by embodiments of the present disclosure, as shown in FIGS. 1 and 8, the input pad groups D further include a second input pad group D2 corresponding to the first sub-group of piezoelectric actuators, and the second input pad group D2 is located in the middle region of the fifth solid region B5. The second input pad group D2 includes a second positive-polarity input pad A2+ and a second negative-polarity input pad A2− arranged along the second direction Y, and the second positive-polarity input pad 1312 is proximate to the fourth solid region B4. In this way, all the positive-polarity connection pads 121 of the first sub-solid region B31 and the third sub-solid region B41 can be electrically connected to the second positive-polarity input pad A2+ through at least one positive-polarity wiring 123 and at least one positive-polarity lead wire 133, and all the negative-polarity connection pads 122 of the first sub-solid region B31 and the third sub-solid region B41 can be electrically connected to the second negative-polarity input pad A2− through at least one negative-polarity wiring 124 and at least one negative-polarity lead wire 134.

In some embodiments, in the above-mentioned haptic feedback component provided by embodiments of the present disclosure, as shown in FIG. 1 and FIG. 6, FIG. 6 only shows the wiring and lead-out structure corresponding to the first sub-solid region B31 and the third sub-solid region B41 in FIG. 1, the positive-polarity wiring 123 corresponding to the first sub-group of piezoelectric actuators and the positive-polarity lead wire 133 corresponding to the first sub-group of piezoelectric actuators are electrically connected by means of a via hole penetrating through the flexible substrate 11. For example, the positive-polarity wiring 123 corresponding to the first sub-group of piezoelectric actuators includes: a second positive-polarity wiring 1232 in the first sub-solid region B31 and extending along the first direction X, and a third positive-polarity wiring 1233 in the third sub-solid region B41 and extending along the first direction X. In some embodiments, the second positive-polarity wiring 1232 is arranged on a side of the first sub-solid region B31 proximate to the hollow region AA, and the third positive-polarity wiring 1233 is arranged on a side of the third sub-solid region B41 away from the hollow region AA. For example, the positive-polarity lead wire 133 corresponding to the first sub-group of piezoelectric actuators includes: a second positive-polarity lead wire 1332 in the second solid region B2 and extending along the second direction Y, and a third positive-polarity lead wire 1333 in the second sub-solid region B32 and extending to the fifth solid region B5 along the shape of the second sub-solid region B32. The second positive-polarity lead wire 1332 is arranged on a side of all the connection pad groups C in the second solid region B2 proximate to the hollow region AA.

In some embodiments, in the above-mentioned haptic feedback component provided by embodiments of the present disclosure, as shown in FIG. 1 and FIG. 6, every two positive-polarity connection pads 121 arranged along the second direction Y in the first sub-solid region B31 are electrically connected to the second positive-polarity wiring 1232 through the first connection line 1251 arranged in the first metal layer 12, and every two positive-polarity connection pads 121 arranged along the second direction Y in the third sub-solid region B41 are electrically connected to the third positive-polarity wiring 1233 through the second connection line 1252 arranged in the first metal layer 12. One end of the second positive-polarity wiring 1232 proximate to the second solid region B2 is electrically connected to one end of the second positive-polarity lead wire 1332 by means of a via hole (V5) penetrating through the flexible substrate 11, the other end of the second positive-polarity lead wire 1332 is electrically connected to one end of the third positive-polarity wiring 1233 proximate to the second solid region B2 by means of a via hole (V6) penetrating through the flexible substrate 11, one end of the second positive-polarity wiring 1232 proximate to the second sub-solid region B32 is electrically connected to one end of the third positive-polarity lead wire 1333 by means of a via (V7) penetrating through the flexible substrate 11, and the other end of the third positive-polarity lead wire 1333 is electrically connected to the second positive-polarity input pad A2+.

In some embodiments, in the above-mentioned haptic feedback component provided by embodiments of the present disclosure, as shown in FIG. 1 and FIG. 6, the negative-polarity wiring 124 corresponding to the first sub-group of piezoelectric actuators and the negative-polarity lead wire 134 corresponding to the first sub-group of piezoelectric actuators are electrically connected by means of a via hole penetrating through the flexible substrate 11. For example, the negative-polarity wirings 124 corresponding to the first sub-group of piezoelectric actuators include: a third negative-polarity wiring 1243 in the first sub-solid region B31 and extending along the first direction X, and a fourth negative-polarity wiring 1244 in the third sub-solid region B41 and extending along the first direction X. The third negative-polarity wiring 1243 is in the first sub-solid region B31 and arranged on a side of the first sub-solid region B31 away from the hollow region AA, and the fourth negative-polarity wiring 1244 is in the third sub-solid region B41 and arranged on a side of the third sub-solid region B41 proximate to the hollow region AA. For example, the negative-polarity lead wires 134 corresponding to the first sub-group of piezoelectric actuators includes: a third negative-polarity lead wire 1343 in the second solid region B2 and extending along the second direction Y, and a fourth negative-polarity lead wire 1344 in the second sub-solid region B32 and extending along the shape of the second sub-solid region B32; where the third negative-polarity lead wire 1343 is located between all the connection pad groups C in the second solid region B2 and the second positive-polarity lead wire 1332.

In some embodiments, in the above-mentioned haptic feedback component provided by embodiments of the present disclosure, as shown in FIG. 1 and FIG. 6, every two negative-polarity connection pads 122 arranged along the second direction Y in the first sub-solid region B31 are electrically connected to the third negative-polarity wiring 1243 by means of the third connection line 1253 in the first metal layer 12. Every two negative-polarity connection pads 122 arranged along the second direction Y in the third sub-solid region B41 are electrically connected to the fourth negative-polarity wiring 1244 by means of the fourth connection line 1254 in the first metal layer 12. One end of the third negative-polarity wiring 1243 proximate to the second solid region B2 is electrically connected to one end of the third negative-polarity lead wire 1343 by means of a via hole (V8) penetrating through the flexible substrate 11, the other end of the third negative-polarity lead wire 1343 is electrically connected to one end of the fourth negative-polarity wiring 1244 proximate to the second solid region B2 by means of a via (V9) penetrating through the flexible substrate 11. One end of the third negative-polarity wiring 1243 proximate to the second sub-solid region B32 is electrically connected to one end of the fourth negative-polarity lead wire 1344 by means of a via hole (V10) penetrating through the flexible substrate 11, and the other end of the fourth negative-polarity lead wire 1344 is electrically connected to the second negative-polarity input pad A2−.

In some embodiments, as shown in FIG. 1 and FIG. 6, each positive-polarity wiring (1232, 1233) corresponding to the first sub-group of piezoelectric actuators is insulated from each negative-polarity wiring (1243, 1244) corresponding to the first sub-group of piezoelectric actuators, and each positive-polarity lead wire (1332, 1333) corresponding to the first sub-group of piezoelectric actuators is insulated from each negative-polarity lead wire (1343, 1344) corresponding to the first sub-group of piezoelectric actuators.

In this way, the positive-polarity lead-out structures 21 of all the piezoelectric actuators 2 in the first sub-solid region B31 and the third sub-solid region B41 are connected in parallel, and the negative-polarity lead-out structures 22 of all the piezoelectric actuators 2 in the first sub-solid region B31 and the third sub-solid region B41 are connected in parallel. By driving all the piezoelectric actuators 2 in the first sub-solid region B31 and the third sub-solid region B41 together, the haptic feedback effect can be improved, and the first sub-solid region B31 and the third sub-solid region B41 can be controlled to be high-frequency driven or low-frequency driven according to the haptic feedback demand. For example, a ground voltage signal is applied to the second negative-polarity input pad A2− through the PCB, and the ground voltage signal is transmitted to the negative-polarity lead-out structure 22 of each piezoelectric actuator 2 through the second negative-polarity input pad A2−, the fourth negative-polarity lead wire 1344, the third negative-polarity wiring 1243, the third negative-polarity lead wire 1343 and the fourth negative-polarity wiring 1244 and the negative-polarity connection pad 122, and an AC voltage signal is applied to the second positive-polarity input pad A2+. The AC voltage signal is transmitted to the positive-polarity lead-out structure 21 of each piezoelectric actuator 2 through the second positive-polarity input pad A2+, the third positive-polarity lead 1333, the second positive-polarity wiring 1232, the second positive-polarity lead 1332, the third positive-polarity wiring 1233 and the positive-polarity connection pad 121, so that an alternating electric field can be formed between the positive-polarity lead-out structure 21 of the piezoelectric actuator 2 and the negative-polarity lead-out structure 22 of the piezoelectric actuator 2. Under the action of the alternating electric field, the piezoelectric actuator 2 generates vibration to achieve haptic feedback.

In some embodiments, in the above-mentioned haptic feedback component provided by embodiments of the present disclosure, as shown in FIG. 1 and FIG. 4, the second sub-solid region B32 and the fourth sub-solid region B42 both include a plurality of piezoelectric actuators 2, the plurality of piezoelectric actuators 2 in the second sub-solid region B32 are arranged in the same column and are arranged in sequence along the first direction X, and the plurality of piezoelectric actuators 2 in the fourth sub-solid region B42 are arranged in the same column and are arranged in sequence along the first direction X. In this way, it can be ensured that the piezoelectric actuators 2 are arranged at each position of the second sub-solid region B32 and the fourth sub-solid region B42, and when the haptic feedback component is integrated in the peripheral region of the cover plate, the haptic feedback effect is improved, and the piezoelectric actuators 2 are arranged in the same column to achieve a local narrow frame.

In some embodiments, in the above-mentioned haptic feedback component provided by embodiments of the present disclosure, as shown in FIG. 1 and FIG. 4, all positive-polarity connection pads 121 in the second sub-solid region B32 are arranged in the same column and arranged in sequence along the first direction X, all negative-polarity connection pads 122 in the second sub-solid region B32 are arranged in the same column and arranged in sequence along the first direction X, the positive-polarity connection pads 121 and the negative-polarity connection pads 122 in the second sub-solid region B32 are arranged in different columns, and the positive-polarity connection pads 121 and the negative-polarity connection pads 122 in the second sub-solid region B32 are alternately arranged along the first direction X. This is conducive to the electrical connection of the positive-polarity wiring 123 and the positive-polarity connection pad 121, and the electrical connection of the negative-polarity wiring 124 and the negative-polarity connection pad 122.

In some embodiments, in the above-mentioned haptic feedback component provided by embodiments of the present disclosure, as shown in FIG. 1 and FIG. 4, all positive-polarity connection pads 121 in the fourth sub-solid region B42 are arranged in the same column and arranged in sequence along the first direction X, all negative-polarity connection pads 122 in the fourth sub-solid region B42 are arranged in the same column and arranged in sequence along the first direction X, the positive-polarity connection pads 121 and the negative-polarity connection pads 122 in the fourth sub-solid region B42 are arranged in different columns, and the positive-polarity connection pads 121 and the negative-polarity connection pads 122 in the fourth sub-solid region B42 are alternately arranged along the first direction X. This is conducive to the electrical connection of the positive-polarity wiring 123 and the positive-polarity connection pad 121, and the electrical connection of the negative-polarity wiring 124 and the negative-polarity connection pad 122.

In some embodiments, in the above-mentioned haptic feedback component provided by embodiments of the present disclosure, as shown in FIG. 1 and FIG. 8, the input pad group D further includes a third input pad group D3 corresponding to the second sub-group of piezoelectric actuators, the third input pad group D3 is located at the corner of the fifth solid region B5 proximate to the third solid region B3, the third input pad group D3 includes a third positive-polarity input pad B1+ and a third negative-polarity input pad B1− arranged along the second direction Y, and the third positive-polarity input pad B1+ is proximate to the fourth solid region B4. In this way, all positive-polarity connection pads 121 in the second sub-solid region B32 and the fourth sub-solid region B42 can be electrically connected to the third positive-polarity input pad B1+ through at least one positive-polarity wiring 123 and at least one positive-polarity lead wire 133, and all negative-polarity connection pads 122 in the second sub-solid region B32 and the fourth sub-solid region B42 can be electrically connected to the third negative-polarity input pad B1− through at least one negative-polarity wiring 124 and at least one negative-polarity lead wire 134.

In some embodiments, in the above-mentioned haptic feedback component provided by embodiments of the present disclosure, as shown in FIG. 1 and FIG. 7, FIG. 7 only shows the wiring and lead-out structure corresponding to the second sub-solid region B32 and the fourth sub-solid region B42 in FIG. 1, the positive-polarity wiring 123 corresponding to the second sub-group of piezoelectric actuators and the positive-polarity lead wire 133 corresponding to the second sub-group of piezoelectric actuators are electrically connected by means of a via hole penetrating through the flexible substrate 11. For example, the positive-polarity wirings 123 corresponding to the second sub-group of piezoelectric actuators include: a fourth positive-polarity wiring 1234 that is sequentially routed along the second sub-solid region B32, the first sub-solid region B31, and the second sub-solid region B2, and a fifth positive-polarity wiring 1235 that is in the fourth sub-solid region B42 and extends along the first direction X. The fourth positive-polarity wiring 1234 is arranged on the sides of the second sub-solid region B32, the first sub-solid region B31, and the second sub-solid region B2 proximate to the hollow region AA, and the fifth positive-polarity wiring 1235 is arranged on the side of the fourth sub-solid region B42 away from the hollow region AA.

For example, the positive-polarity lead wires 133 corresponding to the second sub-group of piezoelectric actuators include: a fourth positive-polarity lead wire 1334 in the third sub-solid region B41 and extending along the first direction X, and a fifth positive-polarity lead wire 1335 located between one end of the fourth positive-polarity line 1234 proximate to the third positive-polarity input pad B1+ and the third positive-polarity input pad B1+.

In some embodiments, in the above-mentioned haptic feedback component provided by embodiments of the present disclosure, as shown in FIGS. 1 and 7, all positive-polarity connection pads 121 in the second sub-solid region B32 are electrically connected to the fourth positive-polarity wiring 1234, all positive-polarity connection pads 121 in the fourth sub-solid region B42 are electrically connected to the fifth positive-polarity wiring 1235. One end of the fourth positive-polarity wiring 1234 proximate to the third sub-solid region B41 is electrically connected to one end of the fourth positive-polarity lead wire 1334 by means of a via hole (V11) penetrating through the flexible substrate 11, the other end of the fourth positive-polarity lead wire 1334 is electrically connected to the fifth positive-polarity wiring 1235 by means of a via hole (V12) penetrating through the flexible substrate 11, one end of the fourth positive-polarity wiring 1234 proximate to the first solid region B1 is electrically connected to one end of the fifth positive-polarity lead wire 1335 by means of a via hole (V13) penetrating through the flexible substrate 11, and the other end of the fifth positive-polarity lead wire 1335 is electrically connected to the third positive-polarity input pad B1+.

In some embodiments, in the above-mentioned haptic feedback component provided by embodiments of the present disclosure, as shown in FIG. 1 and FIG. 7, the negative-polarity wiring 124 corresponding to the second sub-group of piezoelectric actuators and the negative-polarity lead wire 134 corresponding to the second sub-group of piezoelectric actuators are electrically connected by means of a via hole penetrating through the flexible substrate 11. For example, the negative-polarity wirings 124 corresponding to the second sub-group of piezoelectric actuators include: a fifth negative-polarity wiring 1245 sequentially routed along the second sub-solid region B32, the first sub-solid region B31, and the second solid region B2, and a sixth negative-polarity wiring 1246 in the fourth sub-solid region B42 and extending along the first direction X. The fifth negative-polarity wiring 1245 is located between the fourth positive-polarity wiring 1234 and the connection pad group C, and the sixth negative-polarity wiring 1246 is located on the side of the fourth sub-solid region B42 proximate to the hollow region AA.

For example, the negative-polarity lead wires 134 corresponding to the second sub-group of piezoelectric actuators include: a fifth negative-polarity lead wire 1345 in the third sub-solid region B41 and extending along the first direction X, and a sixth negative-polarity lead wire 1346 between one end of the fifth negative-polarity line 1245 proximate to the third negative-polarity input pad B1− and the third negative-polarity input pad B1−.

In some embodiments, in the above-mentioned haptic feedback component provided by embodiments of the present disclosure, as shown in FIGS. 1 and 7, all negative-polarity connection pads 122 in the second sub-solid region B32 are electrically connected to the fifth negative-polarity wiring 1245, all negative-polarity connection pads 122 in the fourth sub-solid region B42 are electrically connected to the sixth negative-polarity wiring 1246. One end of the fifth negative-polarity wiring 1245 proximate to the third sub-solid region B41 is electrically connected to one end of the fifth negative-polarity lead wire 1345 by means of a via hole (V14) penetrating through the flexible substrate 11, the other end of the fifth negative-polarity lead wire 1345 is electrically connected to the sixth negative-polarity wiring 1246 by means of a via hole (V15) penetrating through the flexible substrate 11, one end of the fifth negative-polarity wiring 1245 proximate to the first solid region B1 is electrically connected to one end of the sixth negative-polarity lead wire 1346 by means of a via hole (V16) penetrating through the flexible substrate 11, and the other end of the sixth negative-polarity lead wire 1346 is electrically connected to the third negative-polarity input pad B1−.

In some embodiments, as shown in FIG. 1 and FIG. 7, each positive-polarity wiring (1234, 1235) corresponding to the second sub-group of piezoelectric actuators is insulated from each negative-polarity wiring (1245, 1246) corresponding to the second sub-group of piezoelectric actuators, and each positive-polarity lead wire (1334, 1335) corresponding to the second sub-group of piezoelectric actuators is insulated from each negative-polarity lead wire (1345, 1346) corresponding to the second sub-group of piezoelectric actuators.

In this way, the positive-polarity lead-out structures 21 of all the piezoelectric actuators 2 in the second sub-solid region B32 and the fourth sub-solid region B42 are connected in parallel, and the negative-polarity lead-out structures 22 of all the piezoelectric actuators 2 in the second sub-solid region B32 and the fourth sub-solid region B42 are connected in parallel. By driving all the piezoelectric actuators 2 in the second sub-solid region B32 and the fourth sub-solid region B42 together, the haptic feedback effect can be improved, and the second sub-solid region B32 and the fourth sub-solid region B42 can be controlled to be high-frequency driven or low-frequency driven according to the haptic feedback demand. For example, a ground voltage signal is applied to the third negative-polarity input pad B1− through the PCB, and the ground voltage signal is transmitted to the negative-polarity lead-out structure 22 of each piezoelectric actuator 2 through the third negative-polarity input pad B1−, the sixth negative-polarity lead wire 1346, the fifth negative-polarity wiring 1245, the fifth negative-polarity lead wire 1345, the second negative-polarity wiring 1246 and the negative-polarity connection pad 122. An AC voltage signal is applied to the third positive-polarity input pad B1+, and the AC voltage signal is transmitted to the negative-polarity lead-out structure 22 of each piezoelectric actuator 2 through the positive-polarity input pad B1+, the fifth positive-polarity lead wire 1335, the fourth positive-polarity wiring 1234, the fourth positive-polarity lead wire 1334, the fifth positive-polarity wiring 1235 and the positive-polarity connection pad 121, so that an alternating electric field can be formed between the positive-polarity lead-out structure 21 of the piezoelectric actuator 2 and the negative-polarity lead-out structure 22 of the piezoelectric actuator 2. Under the action of the alternating electric field, the piezoelectric actuator 2 generates vibration to achieve haptic feedback.

It should be noted that the three groups of piezoelectric actuators provided by embodiments of the present disclosure are connected to the corresponding input pad groups through the wirings in the first metal layer and the lead wires in the second metal layer, and the connection of each group is only one of the ways. It only needs to reasonably arrange the wiring and lead wire positions corresponding to the three groups of piezoelectric actuators so that there is no short circuit between the groups.

In some embodiments, in the above-mentioned haptic feedback component provided by embodiments of the present disclosure, as shown in FIG. 1 and FIG. 4 to FIG. 7, the second sub-solid region B32 includes a vertical portion extending along the first direction X and an inclined portion connecting the vertical portion and the first solid region B1, and the second sub-group of piezoelectric actuators is in the vertical portion. Of course, it is not limited to this. For example, the second sub-solid region B32 can only include a vertical portion connecting the first sub-solid region B31 and the first solid region B1, and is set according to the shape of the display region of the display.

In some embodiments, as shown in FIG. 1 and FIG. 5 to FIG. 7, the first solid region B1 and the second solid region B2 can be high-frequency driven, the first sub-solid region B31 and the third sub-solid region B41 can be low-frequency driven, the second sub-solid region B32 and the fourth sub-solid region B42 can be low-frequency driven, and the frequencies corresponding to each region in other schemes can also be adjusted accordingly according to different haptic feedback effects.

In some embodiments, each input pad group (D1, D2, D3) can be connected to an external driving circuit (PCB) through a wire or FPC, and the driving signal emitted by the PCB reaches the positive-polarity lead-out structure and negative-polarity lead-out structure of each piezoelectric actuator through the input pad group and the wiring, thereby driving the piezoelectric actuator to generate a corresponding haptic feedback signal.

It should be noted that the piezoelectric actuator 2 shown in FIG. 1 is divided into three groups as an example, but it is not limited to this. Each solid region of the upper, lower, left and right can be divided into three or more groups, and different groups are driven by different driving signals, which is conducive to fine control of the vibration effect. However, the more groups the piezoelectric actuator 2 is divided into, the wider the width of the corresponding flexible circuit board will be. When integrated with the display, it will occupy more frame space, which is not conducive to achieving a narrow frame.

It should be noted that in FIG. 1 of the embodiment of the present disclosure, each group of piezoelectric actuators 2 is connected in parallel. Of course, each group of piezoelectric actuators 2 can also be connected in series, and the overall drive of the piezoelectric actuators 2 can also be achieved. In addition, compared with the overall parallel drive, the overall series drive can reduce power consumption.

In some embodiments, in the haptic feedback component provided by embodiments of the present disclosure, as shown in FIG. 3, the shape of the piezoelectric actuator 2 can be rectangular, and of course, it can also be other shapes such as a circle, and can be designed according to needs.

In some embodiments, in the above-mentioned haptic feedback component provided by embodiments of the present disclosure, the structure of the piezoelectric actuator is a piezoelectric film or a piezoelectric ceramic block. By using the piezoelectric film or the piezoelectric ceramic block, a given piezoelectric actuator voltage can directly provide vibration excitation, and by utilizing the resonant frequency of some components of the screen module, the structure can generate ultrasonic vibrations, so that the haptic feedback component generates a haptic feedback effect, and the haptic feedback can be adjusted by the squeeze film effect.

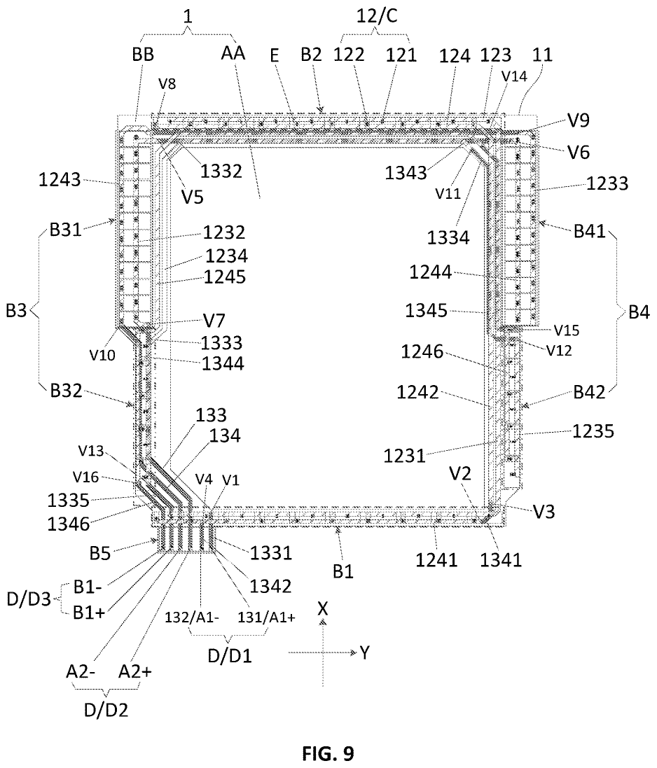

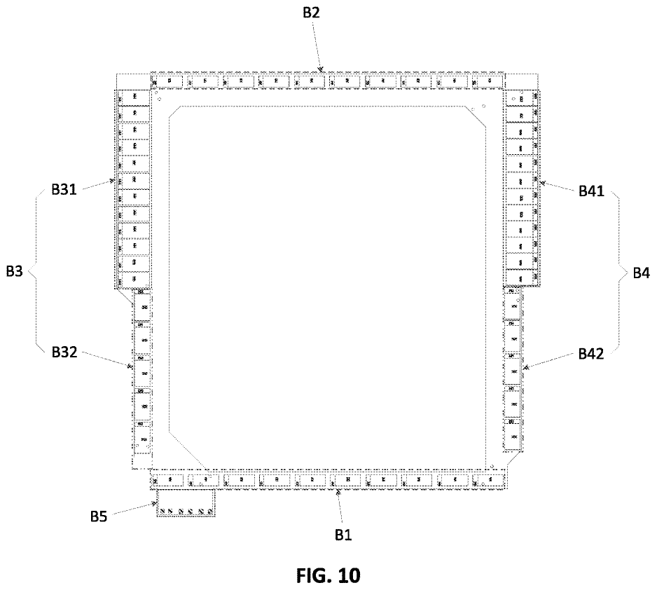

In some embodiments, in the above-mentioned haptic feedback component provided by embodiments of the present disclosure, as shown in FIGS. 9 and 10, FIG. 9 is another top view schematic diagram of a flexible circuit board in haptic feedback component provided by embodiments of the present disclosure, and FIG. 10 is a partition schematic diagram of the piezoelectric actuator connected to the flexible circuit board in FIG. 9. The difference between FIG. 9 and the structure shown in FIG. 1 provided by embodiments of the present disclosure is that the arrangement of the piezoelectric actuator 2 in the first sub-solid region B31 and the third sub-solid region B41 is different and the wiring connection is slightly different.

In some embodiments, as shown in FIGS. 9 and 10, the plurality of piezoelectric actuators 2 in the first sub-solid region B31 are arranged in the same column and are arranged in sequence along the first direction X, the negative-polarity connection pad 122 of each piezoelectric actuator 2 in the first sub-solid region B31 is proximate to the outer edge of the first sub-solid region B31 and is arranged along the first direction X, and the positive-polarity connection pad 121 of each piezoelectric actuator 2 in the first sub-solid region B31 is proximate to the inner edge of the first sub-solid region B31 and is arranged along the first direction X.

The multiple piezoelectric actuators 2 in the third sub-solid region B41 are arranged in the same column and arranged in sequence along the first direction X. The negative-polarity connection pad 122 of each piezoelectric actuator 2 in the third sub-solid region B41 is proximate to the outer edge of the third sub-solid region B41 and arranged along the first direction X. The positive-polarity connection pad 121 of each piezoelectric actuator 2 of the third sub-solid region B41 is proximate to the inner edge of the third sub-solid region B41 and arranged along the first direction X.

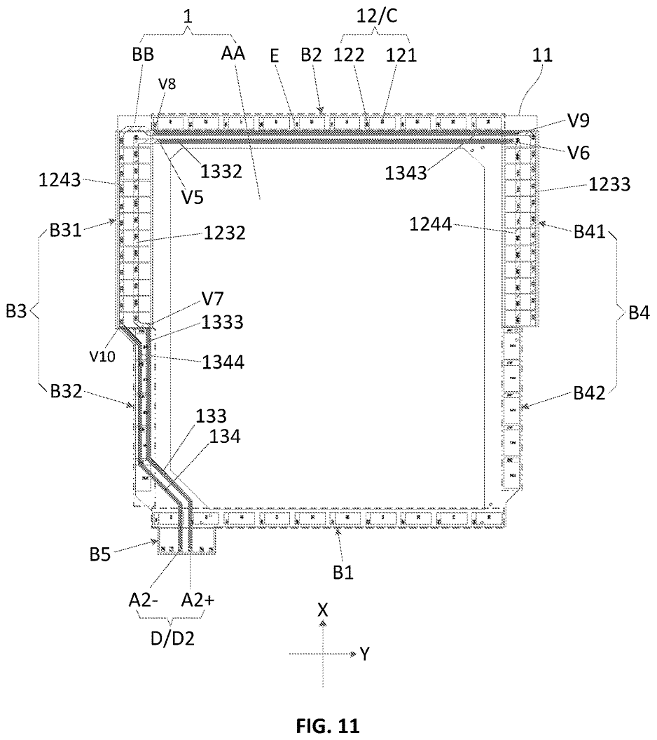

In some embodiments, as shown in FIGS. 9 to 11, FIG. 11 only shows the wiring and lead-out structure corresponding to the first sub-solid region B31 and the third sub-solid region B41 in FIG. 9, all the positive-polarity connection pads 121 in the first sub-solid region B31 are directly electrically connected to the second positive-polarity wiring 1232, all the positive-polarity connection pads 121 in the third sub-solid region B41 are directly electrically connected to the third positive-polarity wiring 1233, all the negative-polarity connection pads 122 in the first sub-solid region B31 are directly electrically connected to the third negative-polarity wiring 1243, and all the negative-polarity connection pads 122 in the third sub-solid region B41 are directly electrically connected to the fourth negative-polarity wiring 1244; the connection method of the positive-polarity lead wires and the negative-polarity lead wires corresponding to the first sub-solid region B31 and the third sub-solid region B41 is the same as that in FIG. 1, and please refer to the relevant description in FIG. 1 for details.

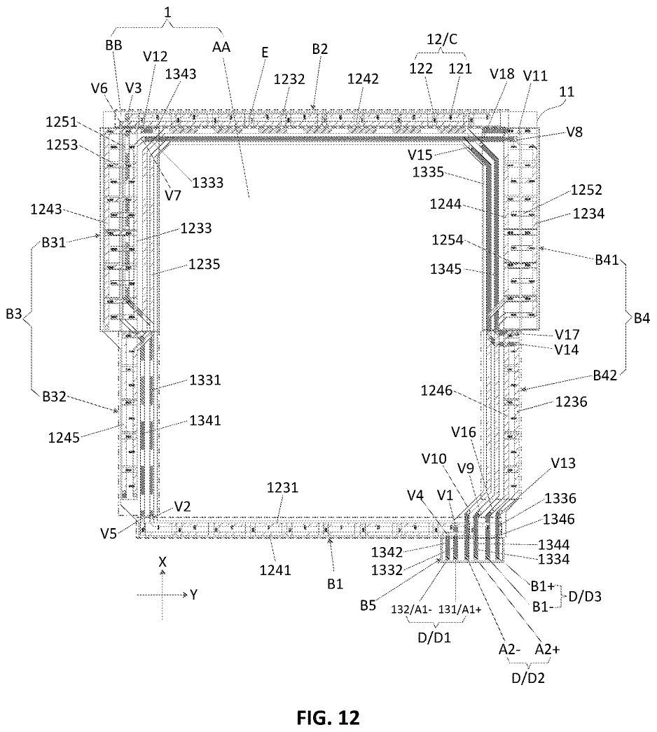

In some embodiments, in the above-mentioned haptic feedback component provided by embodiments of the present disclosure, as shown in FIG. 12, FIG. 12 is a top view schematic diagram of a flexible circuit board in another haptic feedback component provided by embodiments of the present disclosure. One difference between FIG. 12 and the structure shown in FIG. 1 provided by embodiments of the present disclosure is that the fifth solid region B5 is located at the edge of the first solid region B1 and proximate to the fourth solid region B4. Another difference is that the specific connection methods of the wirings and the lead wires corresponding to each group of piezoelectric actuators are different.

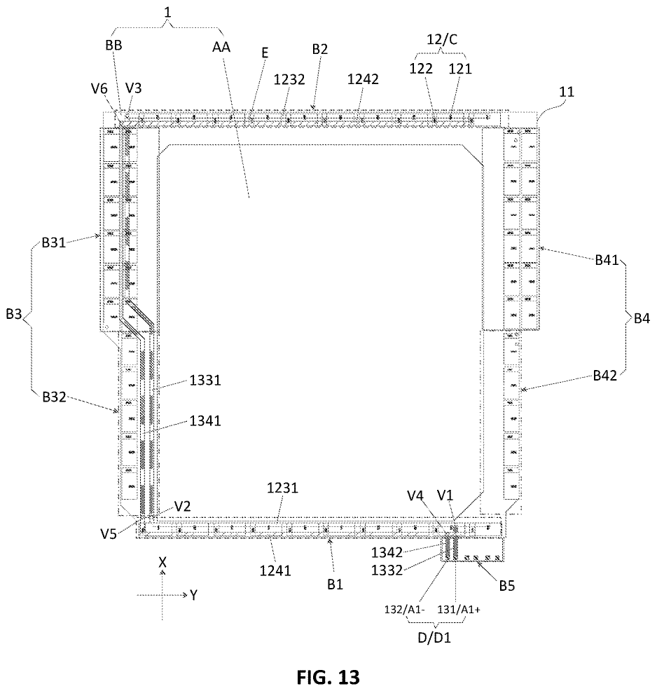

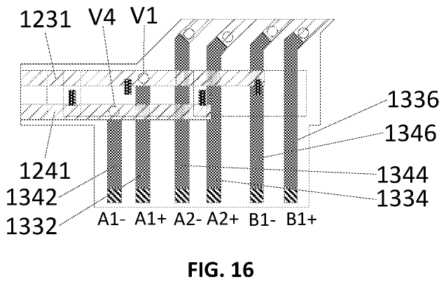

In some embodiments, as shown in FIGS. 12, 13 and 16, FIG. 13 only shows the structures of the wirings and the lead wires in the first solid region B1 and the second solid region B2 in FIG. 12, and FIG. 16 is an enlarged schematic diagram of the fifth solid region B5 and the surrounding region in FIG. 12. For example, the positive-polarity wirings 123 corresponding to the first group of piezoelectric actuators include: a first positive-polarity wiring 1231 in the first solid region B1 and extending along the second direction Y, and a second positive-polarity wiring 1232 in the second solid region B2 and extending along the second direction Y; the first positive-polarity wiring 1231 is located on a side of the first solid region B1 proximate to the hollow region AA, and the second positive-polarity wiring 1232 is located on a side of the second solid region B2 away from the hollow region AA, all positive-polarity connection pads 121 in the first solid region B1 are electrically connected to the first positive-polarity wiring 1231, and all positive-polarity connection pads 121 located in the second solid region B2 are electrically connected to the second positive-polarity wiring 1232. For example, the first The positive-polarity lead wires 133 corresponding to the first group of piezoelectric actuators include: a first positive-polarity lead wire 1331 that runs along the third solid region B3 and follows the shape of the third solid region B3, and a second positive-polarity lead wire 1332 that is in the fifth solid region B5 and extends along the first direction X. One end of the second positive-polarity lead wire 1332 is electrically connected to the first positive-polarity input pad A1+, and the other end of the second positive-polarity lead wire 1332 extends to the first solid region B1 and is electrically connected to the first positive-polarity wiring 1231 by means of a via hole (V1) penetrating through the flexible substrate 11. One end of the first positive-polarity wiring 1231 proximate to the first positive-polarity lead wire 1331 extends to the second sub-solid region B32 and is electrically connected to the first positive-polarity lead wire 1331 by means of the via hole (V2) penetrating through the flexible substrate 11, and one end of the first positive-polarity lead wire 1331 proximate to the second positive-polarity wiring 1232 is electrically connected to the second positive-polarity wiring 1232 by means of the via hole (V3) penetrating through the flexible substrate 11.

In some embodiments, as shown in FIGS. 12, 13 and 16, for example, the negative-polarity wirings 124 corresponding to the first group of piezoelectric actuators include: a first negative-polarity wiring 1241 in the first solid region B1 and extending along the second direction Y, and a second negative-polarity wiring 1242 in the second solid region B2 and extending along the second direction Y. The first negative-polarity wiring 1241 is located on the side of the first solid region B1 away from the hollow region AA, and the second negative-polarity wiring 1242 is located on the side of the second solid region B2 proximate to the hollow region AA, all negative-polarity connection pads 122 in the first solid region B1 are electrically connected to the first negative-polarity wiring 1241, and all negative-polarity connection pads 122 in the second solid region B2 are electrically connected to the second negative-polarity wiring 1242. For example, the negative-polarity lead wire 134 corresponding to the first group of piezoelectric actuators includes: a first negative-polarity lead wire 1341 extending along the third solid region B3 and follows the shape of the third solid region B3, and a second negative-polarity lead wire 1342 in the fifth solid region B5 and extending along the first direction X. One end of the second negative-polarity lead wire 1342 is electrically connected to the first negative-polarity input pad A1−, the other end of the second negative-polarity lead wire 1332 extends to the first solid region B1 and is electrically connected to the first negative-polarity wiring 1241 by means of a via hole (V4) penetrating through the flexible substrate 11, the end of the first negative-polarity wiring 1241 proximate to the first negative-polarity lead wire 1341 extends to the second sub-solid region B32 and is electrically connected to the first negative-polarity lead wire 1341 by means of a via hole (V5) penetrating through the flexible substrate 11, and the end of the first negative-polarity lead wire 1341 proximate to the second negative-polarity wiring 1242 is electrically connected to the second negative-polarity wiring 1242 by means of a via hole (V6) penetrating through the flexible substrate 11.

In this way, the positive-polarity lead-out structures 21 of all piezoelectric actuators 2 in the first solid region B1 and the second solid region B2 are connected in parallel, and the negative-polarity lead-out structures 22 of all piezoelectric actuators 2 in the first solid region B1 and the second solid region B2 are connected in parallel. All piezoelectric actuators 2 in the first solid region B1 and the second solid region B2 are driven together, which can improve the haptic feedback effect. The first solid region B1 and the second solid region B2 are controlled to be driven at a high frequency or a low frequency according to the haptic feedback requirements. For example, a ground voltage signal is applied to the first negative-polarity input pad A1− through the PCB, and the ground voltage signal is transmitted to the negative-polarity lead-out structure 22 of each piezoelectric actuator 2 through the first negative-polarity input pad A1−, the second negative-polarity lead wire 1342, the first negative-polarity wiring 1241, the first negative-polarity lead wire 1341, the second negative-polarity wiring 1242 and the negative-polarity connection pad 122. An AC voltage signal is applied to the first positive-polarity input pad A1+, and the AC voltage signal is transmitted to the positive-polarity lead-out structure 21 of each piezoelectric actuator 2 through the first positive-polarity input pad A1+, the second positive-polarity lead wire 1332, the first positive-polarity wiring 1231, the first positive-polarity lead wire 1331, the second positive-polarity wiring 1232 and the positive-polarity connection pad 121. So that an alternating electric field can be formed between the positive-polarity lead-out structure 21 of the piezoelectric actuator 2 and the negative-polarity lead-out structure 22 of the piezoelectric actuator 2. Under the action of the alternating electric field, the piezoelectric actuator 2 generates vibration to achieve haptic feedback.

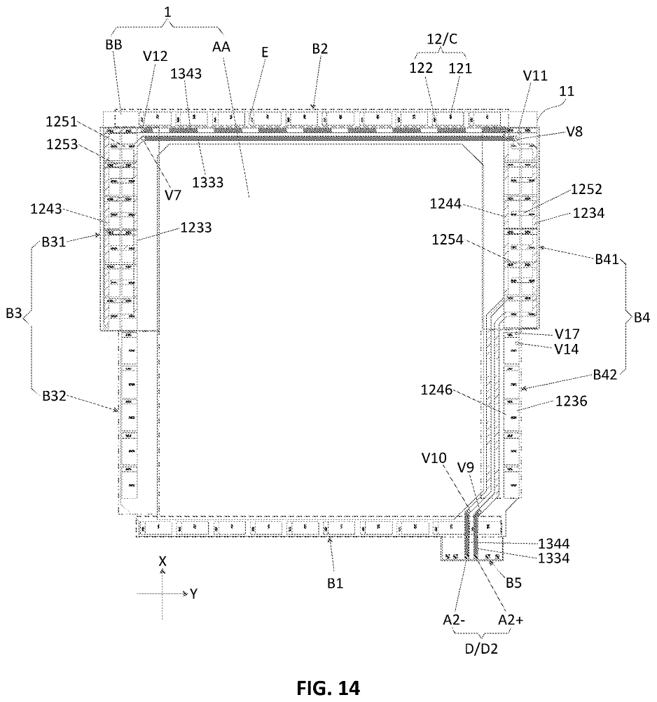

In some embodiments, as shown in FIGS. 12, 14 and 16, FIG. 14 only shows the structures of the wirings and the lead wires in the first sub-solid region B31 and the third sub-solid region B41 in FIG. 12. For example, the positive-polarity wirings 123 corresponding to the first sub-group of piezoelectric actuators include: a third positive-polarity wiring 1233 in the first sub-solid region B31 and extending along the first direction X, and a fourth positive-polarity wiring 1234 in the fourth solid region B4 and following the shape of the fourth solid region B4. The third positive-polarity wiring 1233 is arranged in the first sub-solid region B31 and proximate to the hollow region AA, the fourth positive-polarity wiring 1234 is arranged in the third sub-solid region B41 and away from the hollow region AA. Every two positive-polarity connection pads 121 arranged along the second direction Y in the first sub-solid region B31 are electrically connected to the third positive-polarity wiring 1233 through the first connection line 1251 in the first metal layer 12. Every two positive-polarity connection pads 121 arranged along the second direction Y in the third sub-solid region B41 are electrically connected to the fourth positive-polarity wiring 1234 through the second connection line 1252 in the first metal layer 12. For example, the positive-polarity lead wires 133 corresponding to the first sub-group of piezoelectric actuators include: a third positive-polarity lead wire 1333 in the second solid region B2 and extending along the second direction Y, and a fourth positive-polarity lead wire 1334 in the fifth solid region B5 and extending along the first direction X. One end of the third positive-polarity wiring 1233 proximate to the third positive-polarity lead wire 1333 is electrically connected to the third positive-polarity lead wire 1333 by means of a via hole (V7) penetrating through the flexible substrate 11, one end of the third positive-polarity lead wire 1333 proximate to the fourth positive-polarity wiring 1234 is electrically connected to the fourth positive-polarity wiring 1234 by means of a via hole (V8) penetrating through the flexible substrate 11, one end of the fourth positive-polarity lead wire 1334 is electrically connected to the second positive-polarity input pad A2+, and the other end of the fourth positive-polarity lead wire 1334 extends to the fourth sub-solid region B42 and is electrically connected to the fourth positive-polarity wiring 1234 by means of a via hole (V9) penetrating through the flexible substrate 11.

In some embodiments, as shown in FIGS. 12, 14 and 16, the negative-polarity wirings 124 corresponding to the first sub-group of piezoelectric actuators include: a third negative-polarity wiring 1243 in the first sub-solid region B31 and extending along the first direction X, and a fourth negative-polarity wiring 1244 in the fourth sub-solid region B4 and arranged along the shape of the fourth sub-solid region B4. The third negative-polarity wiring 1243 is arranged in the first sub-solid region B31 and away from the hollow region AA, and the fourth negative-polarity wiring 1244 is arranged in the fourth sub-solid region B4 and proximate to the hollow region AA. Every two negative-polarity connection pads 122 arranged along the second direction Y in the first sub-solid region B31 are electrically connected to the third negative-polarity wiring 1243 through a third connection line 1253 arranged in the first metal layer 12, and every two negative-polarity connection pads 122 arranged along the second direction Y in the third sub-solid region B41 are electrically connected to the fourth negative-polarity wiring 1244 through a fourth connection line 1254 arranged in the first metal layer 12. For example, the negative-polarity lead wires 134 corresponding to the first sub-group of piezoelectric actuators include: a third negative-polarity lead wire 1343 in the second solid region B2 and extending along the second direction Y, and a fourth negative-polarity lead wire 1344 in the fifth solid region B5 and extending along the first direction X. One end of the fourth negative-polarity lead wire 1344 is electrically connected to the second negative-polarity input pad A2−, the other end of the fourth negative-polarity lead wire 1344 extends to the fourth sub-solid region B42 and is electrically connected to the fourth negative-polarity wiring 1244 by means of a via hole (V10) penetrating through the flexible substrate 11, the fourth connection line 1254 is electrically connected to the third negative-polarity lead wire 1343 by means of a via hole (V11) penetrating through the flexible substrate 11, and one end of the third negative-polarity lead wire 1343 proximate to the third negative-polarity wiring 1243 is electrically connected to the third connection line 1253 by means of a via hole (V12) penetrating through the flexible substrate 11.

In this way, the positive-polarity lead-out structures 21 of all the piezoelectric actuators 2 in the first sub-solid region B31 and the third sub-solid region B41 are connected in parallel, and the negative-polarity lead-out structures 22 of all the piezoelectric actuators 2 in the first sub-solid region B31 and the third sub-solid region B41 are connected in parallel. By driving all the piezoelectric actuators 2 in the first sub-solid region B31 and the third sub-solid region B41 together, the haptic feedback effect can be improved, and the first sub-solid region B31 and the third sub-solid region B41 can be controlled to be high-frequency driven or low-frequency driven according to the haptic feedback demand. For example, a ground voltage signal is applied to the second negative-polarity input pad A2− through the PCB, and the ground voltage signal is transmitted to the negative-polarity lead-out structure 22 of each piezoelectric actuator 2 through the second negative-polarity input pad A2−, the fourth negative-polarity wiring 1244, the third negative-polarity lead wire 1343, the third negative-polarity wiring 1243 and the negative-polarity connection pad 122. An AC voltage signal is applied to the second positive-polarity input pad A2+, and the AC voltage signal is transmitted to the positive-polarity lead-out structure 21 of each piezoelectric actuator 2 through the second positive-polarity input pad A2+, the fourth positive-polarity lead wire 1334, the fourth positive-polarity wiring 1234, the third positive-polarity lead wire 1333, the third positive-polarity wiring 1233 and the positive-polarity connection pad 121. So that an alternating electric field can be formed between the positive-polarity lead-out structure 21 of the piezoelectric actuator 2 and the negative-polarity lead-out structure 22 of the piezoelectric actuator 2. Under the action of the alternating electric field, the piezoelectric actuator 2 generates vibration to achieve haptic feedback.

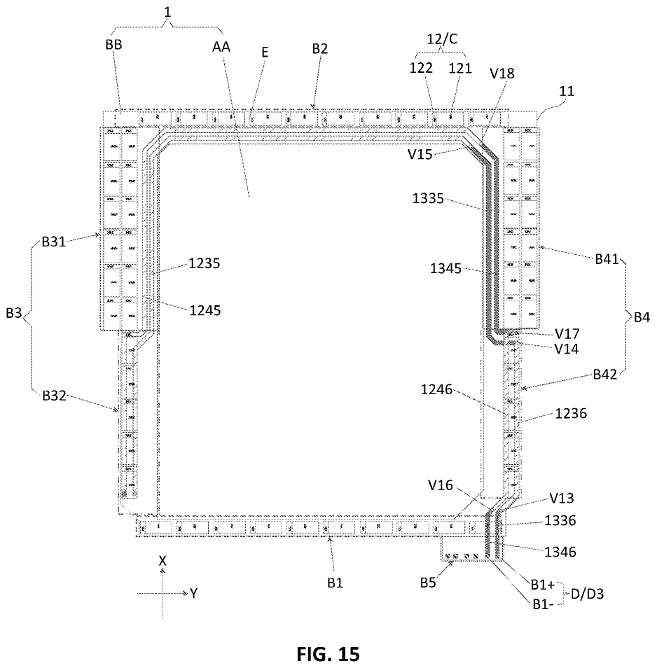

In some embodiments, as shown in FIGS. 12, 15 and 16, FIG. 15 only shows the structures of the wirings and the lead wires in the second sub-solid region B32 and the fourth sub-solid region B42 in FIG. 12, the positive-polarity wirings 123 corresponding to the second sub-group of piezoelectric actuators include: a fifth positive-polarity wiring 1235 along the second sub-solid region B32, the first sub-solid region B31 and the second solid region B2, and a sixth positive-polarity wiring 1236 in the fourth sub-solid region B42 and extending along the first direction X. The fifth positive-polarity wiring 1235 is arranged in the third solid region B3 and proximate to the hollow region AA, the sixth positive-polarity wiring 1236 is arranged in the fourth sub-solid region B42 and away from the hollow region A. All the positive-polarity connection pads 121 in the second sub-solid region B32 are electrically connected to the fifth positive-polarity wiring 1235, and all the positive-polarity connection pads 121 in the fourth sub-solid region B42 are electrically connected to the sixth positive-polarity wiring 1236. For example, the positive-polarity lead wires 133 corresponding to the second sub-group of piezoelectric actuators include: a fifth positive-polarity lead wire 1335 in the third sub-solid region B41 and extending along the first direction X, and a sixth positive-polarity lead wire 1336 in the fifth solid region B5 and extending along the first direction X. One end of the sixth positive-polarity lead wire 1336 is electrically connected to the third positive-polarity input pad B1+, the other end of the sixth positive-polarity lead wire 1336 extends to the fourth sub-solid region B42 and is electrically connected to the sixth positive-polarity wiring 1236 by means of a via hole (V13) penetrating through the flexible substrate 11, one end of the sixth positive-polarity wiring 1236 proximate to the fifth positive-polarity lead wire 1335 is electrically connected to the fifth positive-polarity lead wire 1335 by means of a via hole (V14) penetrating through the flexible substrate 11, and one end of the fifth positive-polarity lead wire 1335 proximate to the fifth positive-polarity wiring 1235 is electrically connected to the fifth positive-polarity wiring 1235 by means of a via hole (V15) penetrating through the flexible substrate 11.

In some embodiments, as shown in FIGS. 12, 15 and 16, the negative-polarity wirings 124 corresponding to the second sub-group of piezoelectric actuators include: a fifth negative-polarity wiring 1245 along the second sub-solid region B32, the first sub-solid region B31 and the second solid region B2, and a sixth negative-polarity wiring 1246 in the fourth sub-solid region B42 and extending along the first direction X. The portion of the fifth negative-polarity wiring 1245 in the second sub-solid region B32 is arranged in the side of the second sub-solid region B32 away from the hollow region AA, the portion of the fifth negative-polarity wiring 1245 in the first sub-solid region B31 is arranged between the third positive-polarity wiring 1233 and the fifth positive-polarity wiring 1235. The sixth negative-polarity wiring 1246 is arranged between the sixth positive-polarity wiring 1236 and the fourth positive-polarity wiring 1234. All the negative-polarity connection pads 122 in the third sub-solid region B32 are electrically connected to the fifth negative-polarity wiring 1245, and all the negative-polarity connection pads 122 in the fourth sub-solid region B42 are electrically connected to the sixth negative-polarity wiring 1246. For example, the negative-polarity lead wires 134 corresponding to the second sub-group of piezoelectric actuators include: a fifth negative-polarity lead wire 1345 in the third sub-solid region B41 and extending along the first direction X, and a sixth negative-polarity lead wire 1346 in the fifth solid region B5 and extending along the first direction X. The fifth negative-polarity lead wire 1345 is located between the fifth positive-polarity lead wire 1335 and the fourth positive-polarity wiring 1244, one end of the sixth negative-polarity lead wire 1346 is electrically connected to the third negative-polarity input pad B1−, and the other end of the sixth negative-polarity lead wire 1346 extends to the fourth sub-solid region B42 and is electrically connected to the sixth negative-polarity wiring 1246 by means of a via hole (V16) penetrating through the flexible substrate 11. One end of the sixth negative-polarity wiring 1246 proximate to the fifth negative-polarity lead wire 1345 is electrically connected to the fifth negative-polarity lead wire 1345 by means of a via hole (V17) penetrating through the flexible substrate 11; and one end of the fifth negative-polarity lead wire 1345 proximate to the fifth negative-polarity wiring 1245 is electrically connected to the fifth negative-polarity wiring 1245 by means of a via hole (V18) penetrating through the flexible substrate 11.

In this way, the positive-polarity lead-out structures 21 of all the piezoelectric actuators 2 in the second sub-solid region B32 and the fourth sub-solid region B42 are connected in parallel, and the negative-polarity lead-out structures 22 of all the piezoelectric actuators 2 in the second sub-solid region B32 and the fourth sub-solid region B42 are connected in parallel. By driving all the piezoelectric actuators 2 in the second sub-solid region B32 and the fourth sub-solid region B42 together, the haptic feedback effect can be improved, and the second sub-solid region B32 and the fourth sub-solid region B42 can be controlled to be high-frequency driven or low-frequency driven according to the haptic feedback demand. For example, a ground voltage signal is applied to the third negative-polarity input pad B1− through the PCB, and the ground voltage signal is transmitted to the negative-polarity lead-out structure 22 of each piezoelectric actuator 2 through the third negative-polarity input pad B1−, the fifth negative-polarity lead wire 1346, the sixth negative-polarity wiring 1246, the third negative-polarity lead wire 1345, the fifth negative-polarity wiring 1245 and the negative-polarity connection pad 122. An AC voltage signal is applied to the third positive-polarity input pad B1+, and the AC voltage signal is transmitted to the positive-polarity lead-out structure 21 of each piezoelectric actuator 2 through the third positive-polarity input pad B1+, the sixth positive-polarity lead wire 1336, the sixth positive-polarity wiring 1236, the fifth positive-polarity lead wire 1335, the fifth positive-polarity wiring 1235 and the positive-polarity connection pad 121. So that an alternating electric field can be formed between the positive-polarity lead-out structure 21 of the piezoelectric actuator 2 and the negative-polarity lead-out structure 22 of the piezoelectric actuator 2. Under the action of the alternating electric field, the piezoelectric actuator 2 generates vibration to achieve haptic feedback.

It should be noted that the positions of the wirings with the same labels in FIG. 12 and FIG. 1 can be different or the same; the positions of the lead wires with the same labels in FIG. 12 and FIG. 1 can be different or the same.

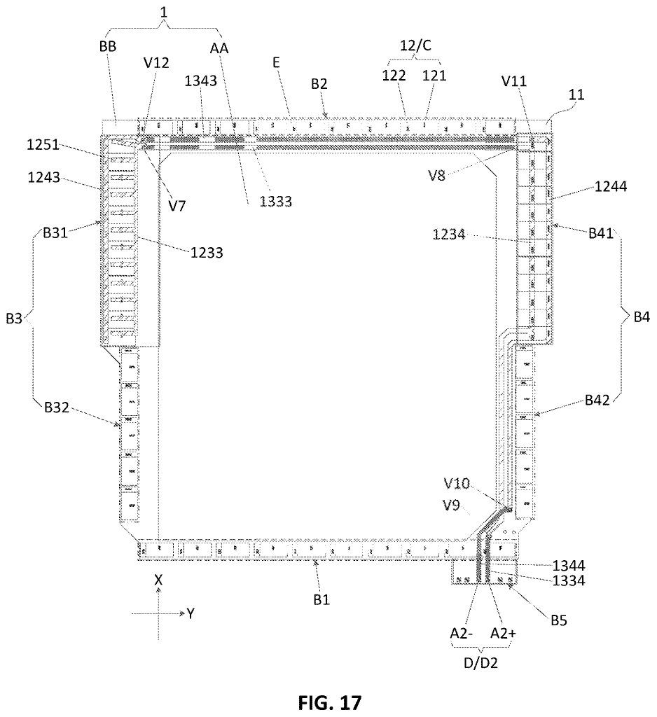

In some embodiments, in the above-mentioned haptic feedback component provided by embodiments of the present disclosure, as shown in FIG. 17, FIG. 17 is a top view schematic diagram of a flexible circuit board in another haptic feedback component provided by embodiments of the present disclosure. The difference between FIG. 17 and the structure shown in FIG. 12 provided by embodiments of the present disclosure is that the arrangement of the piezoelectric actuator 2 in the first sub-solid region B31 and the third sub-solid region B41 is different and the wiring connection is slightly different. FIG. 17 only shows the wiring and lead-out structure corresponding to the first sub-solid region B31 and the third sub-solid region B41.

In some embodiments, as shown in FIG. 17, the plurality of piezoelectric actuators 2 in the first sub-solid region B31 are arranged in the same column and are arranged in sequence along the first direction X, the negative-polarity connection pad 122 of each piezoelectric actuator 2 in the first sub-solid region B31 is proximate to the outer edge of the first sub-solid region B31 and is arranged along the first direction X, and the positive-polarity connection pad 121 of each piezoelectric actuator 2 in the first sub-solid region B31 is proximate to the inner edge of the first sub-solid region B31 and is arranged along the first direction X.

The multiple piezoelectric actuators 2 in the third sub-solid region B41 are arranged in the same column and arranged in sequence along the first direction X. The negative-polarity connection pad 122 of each piezoelectric actuator 2 in the third sub-solid region B41 is proximate to the outer edge of the third sub-solid region B41 and arranged along the first direction X. The positive-polarity connection pad 121 of each piezoelectric actuator 2 in the third sub-solid region B41 is proximate to the inner edge of the third sub-solid region B41 and arranged along the first direction X.

In some embodiments, as shown in FIG. 17, all negative-polarity connection pads 122 in the first sub-solid region B31 are directly electrically connected to the third negative-polarity wiring 1243, the portion of the fourth negative-polarity wiring 1244 in the third sub-solid region B41 is located on the side away from the hollow region AA, the portion of the fourth negative-polarity wiring 1244 in the fourth sub-solid region B42 is located between the fourth positive-polarity wiring 1234 and the sixth negative-polarity wiring 1246. All negative-polarity connection pads 122 in the third sub-solid region B41 are directly electrically connected to the fourth negative-polarity wiring 1244, all positive-polarity connection pads 122 in the third sub-solid region B41 are directly electrically connected to the fourth positive-polarity wiring 1234, and the orthographic projections of the fourth positive-polarity wiring 1234 and the fourth negative-polarity lead wire 1344 on the flexible substrate 11 are cross-arranged. The connection method of the positive-polarity lead wire and the negative-polarity lead wire corresponding to the first sub-solid region B31 and the third sub-solid region B41 is the same as that in FIG. 12, and specifically refer to the relevant description in FIG. 12.

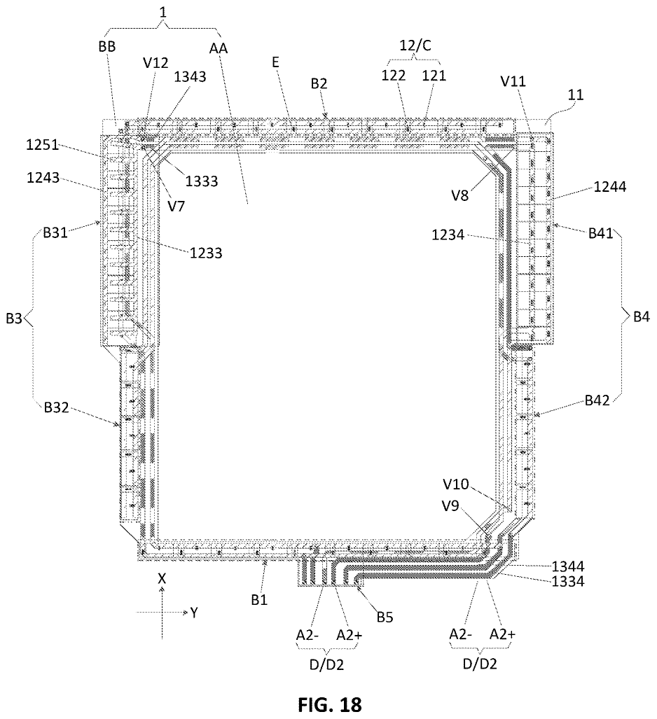

In some embodiments, in the above-mentioned haptic feedback component provided by embodiments of the present disclosure, as shown in FIG. 18, FIG. 18 is a top view schematic diagram of a flexible circuit board in another haptic feedback component provided by embodiments of the present disclosure. The difference between FIG. 18 and the structure shown in FIG. 17 provided by embodiments of the present disclosure is that the position of the fifth solid region B5 is different. The fifth solid region B5 in FIG. 18 is located in the middle region of the first solid region B1, and the wiring connection method of each group of piezoelectric actuators is the same, except that all positive-polarity and negative-polarity lead wires are extended to the middle position in the first solid region B1 and connected to the corresponding pad group.

In some embodiments, the fifth solid region B5 in FIG. 1, FIG. 9 and FIG. 12 can also be located in the middle region of the first solid region B1.

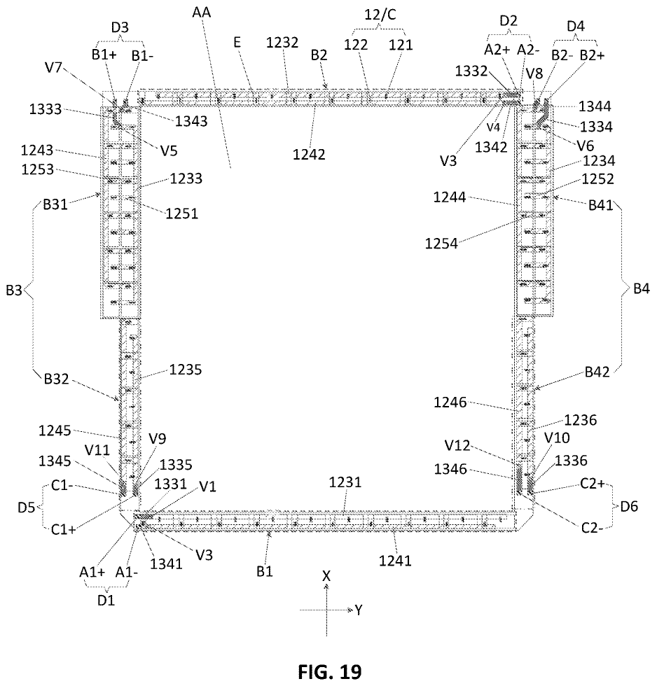

In some embodiments, in the above-mentioned haptic feedback component provided by embodiments of the present disclosure, as shown in FIG. 19, FIG. 19 is a top view schematic diagram of a flexible circuit board in another haptic feedback component provided by embodiments of the present disclosure, and the difference between the structure of FIG. 19 and FIG. 1 is that the fifth solid region B5 is not provided, the position of the input pad group D is different, and the wiring method needs to be changed. Compared with the structure of FIG. 1, FIG. 19 lacks the fifth solid region B5, which can narrow the region of the flexible circuit board, so when the haptic feedback component shown in FIG. 19 is integrated with the display or touch substrate, a narrow frame can be further achieved.

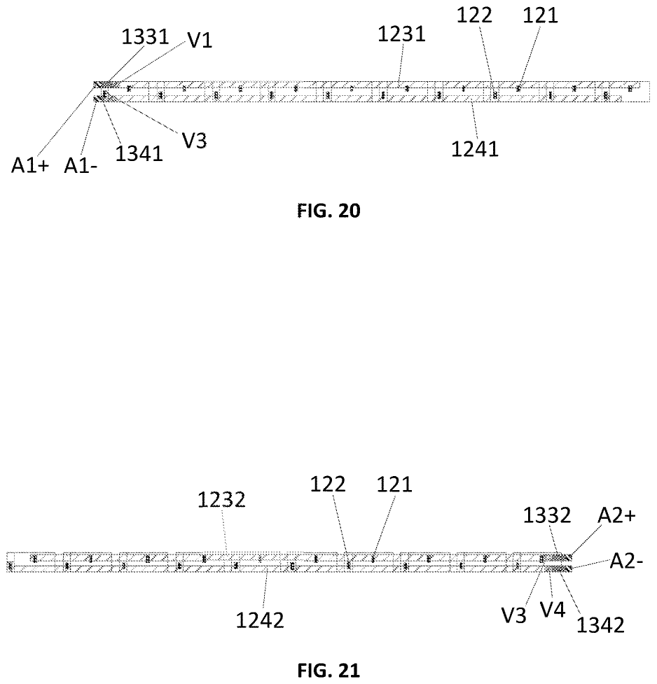

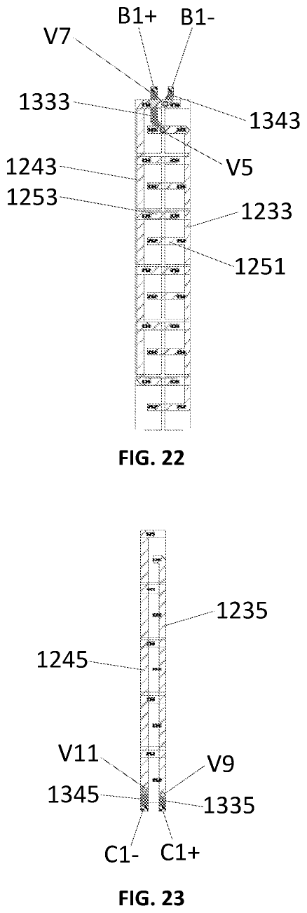

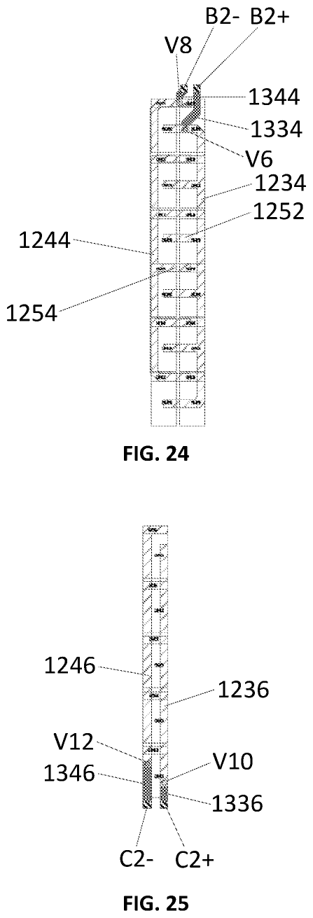

In some embodiments, as shown in FIGS. 19 to 25, FIG. 20 is a schematic diagram of the structure of the first solid region in FIG. 19, FIG. 21 is a schematic diagram of the structure of the second solid region in FIG. 19, FIG. 22 is a schematic diagram of the structure of the first sub-solid region in FIG. 19, FIG. 23 is a schematic diagram of the structure of the second sub-solid region in FIG. 19, FIG. 24 is a schematic diagram of the structure of the third sub-solid region in FIG. 19, and FIG. 25 is a schematic diagram of the structure of the fourth sub-solid region in FIG. 19. The input pad group D includes: a first input pad group D1 in the first solid region B1 and corresponding to the piezoelectric actuator 2 in the first solid region B1, and a second input pad group D2 in the second solid region B2 and corresponding to the piezoelectric actuator 2 in the second solid region B2. The first input pad group D1 includes a first positive-polarity input pad A1+ and a first negative-polarity input pad A1−, the second input pad group D2 includes a second positive-polarity input pad A2+ and a second negative-polarity input pad A2−. The first positive-polarity input pad A1+ and the second positive-polarity input pad A2+ are electrically connected to the first positive-polarity driving signal terminal (not shown in the figures), that is, the first positive-polarity input pad A1+ and the second positive-polarity input pad A2+ are connected to the same positive-polarity driving signal. The first negative-polarity input pad A1− and the second negative-polarity input pad A2− are electrically connected to the first negative-polarity driving signal terminal (not shown in the figures), that is, the first negative-polarity input pad A1− and the second negative-polarity input pad A2− are connected to the same negative-polarity driving signal. In this way, the positive-polarity lead-out structures 21 of all piezoelectric actuators 2 in the first solid region B1 and the second solid region B2 can be connected in parallel, and the negative-polarity lead-out structures 22 of all piezoelectric actuators 2 in the first solid region B1 and the second solid region B2 can be connected in parallel, and all piezoelectric actuators 2 in the first solid region B1 and the second solid region B2 can be driven together, which can improve the haptic feedback effect, and the second sub-solid region B32 and the fourth sub-solid region B42 can be controlled to be high-frequency driven or low-frequency driven according to the haptic feedback requirements.

In some embodiments, as shown in FIG. 19, the input pad group D further includes: a third input pad group D3 in the first sub-solid region B31 and corresponding to the piezoelectric actuator 2 in the first sub-solid region B31, and a fourth input pad group D4 in the third sub-solid region B41 and corresponding to the piezoelectric actuator 2 in the third sub-solid region B41. The third input pad group D3 includes a third positive-polarity input pad B1+ and a third negative-polarity input pad B1−, and the fourth input pad group D4 includes a fourth positive-polarity input pad B2+ and a fourth negative-polarity input pad B2−. The third positive-polarity input pad B1+ and the fourth positive-polarity input pad B2+ are electrically connected to the second positive-polarity driving signal terminal (not shown in the figures), that is, the third positive-polarity input pad B1+ and the fourth positive-polarity input pad B2+ are connected to the same positive-polarity driving signal terminal. The third negative-polarity input pad B1− and the fourth negative-polarity input pad B2− are electrically connected to the second negative-polarity drive signal terminal (not shown in the figures), that is, the third negative-polarity input pad B1− and the fourth negative-polarity input pad B2− are connected to the same negative-polarity drive signal terminal. In this way, the positive-polarity lead-out structures 21 of all piezoelectric actuators 2 in the first sub-solid region B31 and the third sub-solid region B41 can be connected in parallel, and the negative-polarity lead-out structures 22 of all piezoelectric actuators 2 in the first sub-solid region B31 and the third sub-solid region B41 can be connected in parallel. All piezoelectric actuators 2 in the first sub-solid region B31 and the third sub-solid region B41 are driven together, which can improve the haptic feedback effect, and the first sub-solid region B31 and the third sub-solid region B41 are controlled to be high-frequency driven or low-frequency driven according to the haptic feedback requirements.

In some embodiments, as shown in FIG. 19, the input pad group D includes: a fifth input pad group D5 in the second sub-solid region B32 and corresponding to the piezoelectric actuator 2 in the second sub-solid region B32, and a sixth input pad group D6 in the fourth sub-solid region B42 and corresponding to the piezoelectric actuator 2 in the fourth sub-solid region B42. The fifth input pad group D5 includes a fifth positive-polarity input pad C1+ and a fifth negative-polarity input pad C1−, the sixth input pad group D6 includes a sixth positive-polarity input pad C2+ and a sixth negative-polarity input pad C2−. The fifth positive-polarity input pad C1+ and the sixth positive-polarity input pad C2+ are electrically connected to the third positive-polarity drive signal terminal (not shown in the figures), that is, the fifth positive-polarity input pad C1+ and the sixth positive-polarity input pad C2+ are connected to the same positive-polarity drive signal terminal. The fifth negative-polarity input pad C1− and the sixth negative-polarity input pad C2− are electrically connected to the third negative-polarity drive signal terminal (not shown in the figures), that is, the fifth negative-polarity input pad C1− and the sixth negative-polarity input pad C2− are connected to the same negative-polarity drive signal terminal. In this way, the positive-polarity lead-out structures 21 of all piezoelectric actuators 2 in the second sub-solid region B32 and the fourth sub-solid region B42 can be connected in parallel, and the negative-polarity lead-out structures 22 of all piezoelectric actuators 2 in the second sub-solid region B32 and the fourth sub-solid region B42 can be connected in parallel, and all piezoelectric actuators 2 in the second sub-solid region B32 and the fourth sub-solid region B42 can be driven together, which can improve the haptic feedback effect, and the second sub-solid region B32 and the fourth sub-solid region B42 can be controlled to be high-frequency driven or low-frequency driven according to the haptic feedback requirements.

In some embodiments, in the above-mentioned haptic feedback component provided by embodiments of the present disclosure, as shown in FIG. 19, the first input pad group D1 can be located at one end of the first solid region B1, and the second input pad group D2 can be located at one end of the second solid region B2.

The third input pad group D3 can be located at one end of the first sub-solid region B31, the fourth input pad group D4 can be located at one end of the third sub-solid region B41, and the third input pad group D3 and the fourth input pad group D4 can be proximate to the second solid region B2.

The fifth input pad group D5 can be located at one end of the second sub-solid region B32, the sixth input pad group D6 can be located at one end of the fourth sub-solid region B42, and the fifth input pad group D5 and the sixth input pad group D6 can be proximate to the first solid region.

In some embodiments, as shown in FIGS. 19 to 21, the positive-polarity wirings 123 corresponding to the first group of piezoelectric actuators include: a first positive-polarity wiring 1231 in the first solid region B1 and extending along the second direction Y, and a second positive-polarity wiring 1232 in the second solid region B2 and extending along the second direction Y. The first positive-polarity wiring 1231 is proximate to the hollow region AA, and the second positive-polarity wiring 1232 is away from the hollow region AA. The positive-polarity lead wires 133 corresponding to the first group of piezoelectric actuators include: a first positive-polarity lead wire 1331 in the first solid region B1 proximate to the edge of the second sub-solid region B32 and extending along the second direction Y, and a second positive-polarity lead wire 1332 in the second solid region B2 proximate to the edge of the third sub-solid region B41 and extending along the second direction Y. All positive-polarity connection pads 121 in the first solid region B1 are electrically connected to the first positive-polarity wiring 1231; and all positive-polarity connection pads 121 in the second solid region B2 are electrically connected to the second positive-polarity wiring 1232. One end of the first positive-polarity wiring 1231 proximate to the first positive-polarity lead wire 1331 is electrically connected to one end of the first positive-polarity lead wire 1331 by means of a via hole (V1) penetrating through the flexible substrate 11, and the other end of the first positive-polarity lead wire 1331 is electrically connected to the first positive-polarity input pad A1+. One end of the second positive-polarity wiring 1232 proximate to the second positive-polarity lead wire 1332 is electrically connected to one end of the second positive-polarity lead wire 1332 by means of a via hole (V2) penetrating through the flexible substrate 11, and the other end of the second positive-polarity lead wire 1332 is electrically connected to the second positive-polarity input pad A2+.

In some embodiments, as shown in FIGS. 19 to 21, the negative-polarity wirings 124 corresponding to the first group of piezoelectric actuators include: a first negative-polarity wiring 1241 in the first solid region B1 and extending along the second direction Y, and a second negative-polarity wiring 1242 in the second solid region B2 and extending along the second direction Y. The first negative-polarity wiring 1241 is away from the hollow region AA, and the second negative-polarity wiring 1242 is proximate to the hollow region AA. The negative-polarity lead wires 134 corresponding to the first group of piezoelectric actuators include: a first negative-polarity lead wire 1341 in the first solid region B1 proximate to the edge of the second sub-solid region B32 and extending along the second direction Y, and a second negative-polarity lead wire 1342 in the second solid region B2 proximate to the edge of the third sub-solid region B41 and extending along the second direction Y. All negative-polarity connection pads 122 in the first solid region B1 are electrically connected to the first negative-polarity wiring 1241; and all negative-polarity connection pads 122 in the second solid region B2 are electrically connected to the second negative-polarity wiring 1242. One end of the first negative-polarity wiring 1241 proximate to the first negative-polarity lead wire 1341 is electrically connected to one end of the first negative-polarity lead wire 1341 by means of a via hole (V3) penetrating through the flexible substrate 11, and the other end of the first negative-polarity lead wire 1341 is electrically connected to the first negative-polarity input pad A1−. One end of the second negative-polarity wiring 1242 proximate to the second negative-polarity lead wire 1342 is electrically connected to one end of the second negative-polarity lead wire 1342 by means of a via hole (V4) penetrating through the flexible substrate 11, and the other end of the second negative-polarity lead wire 1342 is electrically connected to the second negative-polarity input pad A2−.

In some embodiments, as shown in FIGS. 19, 22 and 24, the positive-polarity wirings 123 corresponding to the first sub-group of piezoelectric actuators include: a third positive-polarity wiring 1233 in the first sub-solid region B31 and extending along the first direction X, and a fourth positive-polarity wiring 1234 in the third sub-solid region B41 and extending along the first direction X. The third positive-polarity wiring 1233 is proximate to the hollow region AA, and the fourth positive-polarity wiring 1234 is away from the hollow region AA. The positive-polarity lead wires 133 corresponding to the first sub-group of piezoelectric actuators further include: a third positive-polarity lead wire 1333 in the first sub-solid region B31 proximate to the edge of the second solid region B2 and extending along the first direction X, and a fourth positive-polarity lead wire 1334 in the third sub-solid region B41 proximate to the edge of the second solid region B2 and extending along the first direction X. Every two positive-polarity connection pads 121 arranged along the second direction Y in the first sub-solid region B31 are electrically connected to the third positive-polarity wiring 1233 through the first connection line 1251 in the first metal layer 12, and one end of the third positive-polarity lead wire 1333 proximate to the first connection line 1251 is electrically connected to the first connection line 1251 by means of a via hole (V5) penetrating through the flexible substrate 11, and the other end of the third positive-polarity lead wire 1333 is electrically connected to the third positive-polarity input pad B1+. Every two positive-polarity connection pads 121 arranged along the second direction Y in the third sub-solid region B41 are electrically connected to the fourth positive-polarity wiring 1234 through the second connection line 1252 in the first metal layer 12, and one end of the fourth positive-polarity lead wire 1334 proximate to the second connection line 1252 is electrically connected to the second connection line 1252 by means of a via hole (V6) penetrating through the flexible substrate 11, and the other end of the fourth positive-polarity lead wire 1334 is electrically connected to the fourth positive-polarity input pad B2+.

In some embodiments, as shown in FIGS. 19, 22 and 24, the negative-polarity wirings 124 corresponding to the first sub-group of piezoelectric actuators include: a third negative-polarity wiring 1243 in the first sub-solid region B31 and extending along the first direction X, and a fourth negative-polarity wiring 1244 in the third sub-solid region B41 and extending along the first direction X; the third negative-polarity wiring 1243 is away from the hollow region AA, and the fourth negative-polarity wiring 1244 is proximate to the hollow region AA. The negative-polarity lead wires 134 corresponding to the first sub-group of piezoelectric actuators further include: a third negative-polarity lead wire 1343 located at the edge of the first sub-solid region B31 proximate to the second sub-solid region B2 and extending along the first direction X, and a fourth negative-polarity lead wire 1344 located at the edge of the third sub-solid region B41 proximate to the second sub-solid region B2 and extending along the first direction X. The third negative-polarity lead wire 1343 is located at a side of the third positive-polarity lead wire 1333 proximate to the hollow region AA, and the fourth negative-polarity lead wire 1344 is located at a side of the fourth positive-polarity lead wire 1334 proximate to the hollow region AA. Every two negative-polarity connection pads 122 arranged along the second direction Y in the first sub-solid region B31 are electrically connected to the third negative-polarity wiring 1243 through the third connection line 1253 in the first metal layer 12. One end of the third negative-polarity lead wire 1343 proximate to the third connection line 1253 is electrically connected to the third connection line 1253 by means of a via hole (V7) penetrating through the flexible substrate 11, and the other end of the third negative-polarity lead wire 1343 is electrically connected to the third negative-polarity input pad B1−. Every two negative-polarity connection pads 122 arranged along the second direction Y in the fourth sub-solid region B41 are electrically connected to the fourth negative-polarity wiring 1244 through the fourth connection line 1254 in the first metal layer 12. One end of the fourth negative-polarity lead wire 1344 proximate to the fourth connection line 1254 is electrically connected to the fourth connection line 1254 by means of a via hole (V8) penetrating through the flexible substrate 11, and the other end of the fourth negative-polarity lead wire 1344 is electrically connected to the fourth negative-polarity input pad B2−.

In some embodiments, as shown in FIGS. 19, 23 and 25, the positive-polarity wirings 123 corresponding to the second sub-group of piezoelectric actuators include: a fifth positive-polarity wiring 1235 in the second sub-solid region B32 and extending along the first direction X, and a sixth positive-polarity wiring 1236 in the fourth sub-solid region B42 and extending along the first direction X. The fifth positive-polarity wiring 1235 is proximate to the hollow region AA, and the sixth positive-polarity wiring 1236 is away from the hollow region AA. The positive-polarity lead wires 133 corresponding to the second sub-group of piezoelectric actuators include: a fifth positive-polarity lead wire 1335 located in the edge of the second sub-solid region B32 proximate to the first sub-solid region B1 and extending along the first direction X, and a sixth positive-polarity lead wire 1336 located in the edge of the fourth sub-solid region B42 proximate to the first sub-solid region B1 and extending along the first direction X. All positive-polarity connection pads 121 in the second sub-solid region B32 are electrically connected to the fifth positive-polarity wiring 1235, and one end of the fifth positive-polarity wiring 1235 proximate to the fifth positive-polarity lead wire 1335 is electrically connected to one end of the fifth positive-polarity lead wire 1335 by means of a via (V9) penetrating through the flexible substrate 11, and the other end of the fifth positive-polarity lead wire 1335 is electrically connected to the fifth positive-polarity input pad C1+. All positive-polarity connection pads 121 in the fourth sub-solid region B42 are electrically connected to the sixth positive-polarity wiring 1236, and one end of the sixth positive-polarity wiring 1236 proximate to the sixth positive-polarity lead wire 1336 is electrically connected to one end of the sixth positive-polarity lead wire 1336 by means of a via hole (V10) penetrating through the flexible substrate 11, and the other end of the sixth positive-polarity lead wire 1336 is electrically connected to the sixth positive-polarity input pad C2+.

In some embodiments, as shown in FIGS. 19, 23 and 25, the negative-polarity wirings 124 corresponding to the second sub-group of piezoelectric actuators include: a fifth negative-polarity wiring 1245 in the second sub-solid region B32 and extending along the first direction X, and a sixth negative-polarity wiring 1246 in the fourth sub-solid region B42 and extending along the first direction X; the fifth negative-polarity wiring 1245 is away from the hollow region AA, and the sixth negative-polarity wiring 1246 is proximate to the hollow region AA. The negative-polarity lead wires 134 corresponding to the second sub-group of piezoelectric actuators include: a fifth negative-polarity lead wire 1345 located in the edge of the second sub-solid region B32 proximate to the first sub-solid region B1 and extending along the first direction X, and a sixth negative-polarity lead wire 1346 located in the edge of the fourth sub-solid region B42 proximate to the first sub-solid region B1 and extending along the first direction X. All negative-polarity connection pads 122 in the second sub-solid region B32 are electrically connected to the fifth negative-polarity wiring 1245, and one end of the fifth negative-polarity wiring 1245 proximate to the fifth negative-polarity lead wire 1345 is electrically connected to one end of the fifth negative-polarity lead wire 1345 by means of a via hole (V11) penetrating through the flexible substrate 11, and the other end of the fifth negative-polarity lead wire 1345 is electrically connected to the fifth negative-polarity input pad C1−. All negative-polarity connection pads 122 in the fourth sub-solid region B42 are electrically connected to the sixth negative-polarity wiring 1246, and one end of the sixth negative-polarity wiring 1246 proximate to the sixth negative-polarity lead wire 1346 is electrically connected to one end of the sixth negative-polarity lead wire 1346 by means of a via hole (V12) penetrating through the flexible substrate 11, and the other end of the sixth negative-polarity lead wire 1346 is electrically connected to the sixth negative-polarity input pad C2−.

It should be noted that the positions of the wirings with the same labels in FIG. 19 and FIG. 1 can be different or the same; the positions of the lead wires with the same labels in FIG. 19 and FIG. 1 can be different or the same.

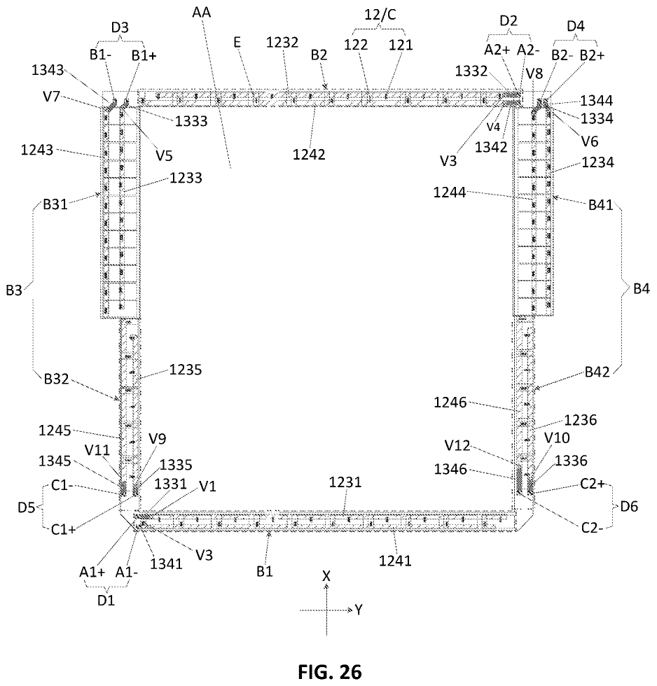

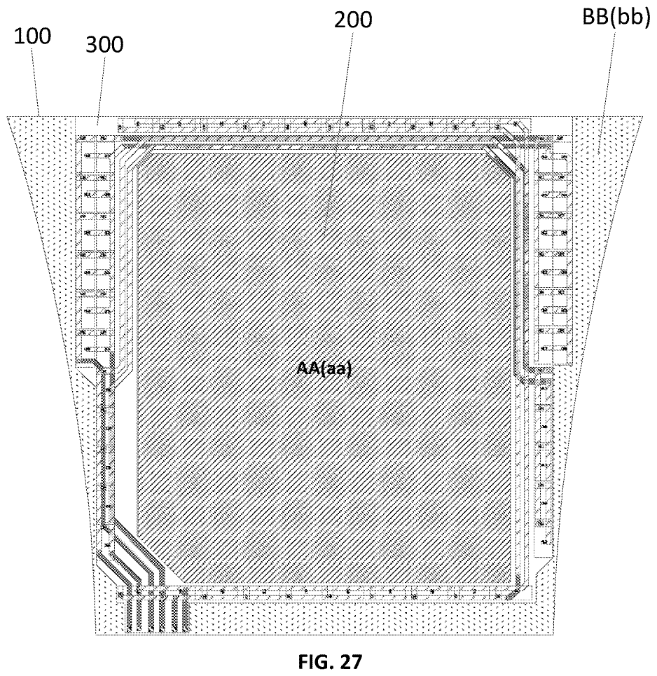

In some embodiments, in the above-mentioned haptic feedback component provided by embodiments of the present disclosure, as shown in FIG. 26, FIG. 26 is a top view schematic diagram of a flexible circuit board in another haptic feedback component provided by embodiments of the present disclosure, and the structural difference between FIG. 26 and FIG. 19 is that the arrangement of the piezoelectric actuators in the first sub-solid region B31 and the third sub-solid region B41 is different and the wiring method needs to be changed. The arrangement of the piezoelectric actuators 2 in the first sub-solid region B31 and the third sub-solid region B41 in FIG. 26 is the same as that in FIG. 9. As shown in FIG. 26, all positive-polarity connection pads 121 in the first sub-solid region B31 are directly electrically connected to the third positive-polarity wiring 1233, all negative-polarity connection pads 122 in the first sub-solid region B31 are directly electrically connected to the third negative-polarity wiring 1243, all positive-polarity connection pads 121 in the third sub-solid region B41 are directly electrically connected to the fourth positive-polarity wiring 1234, and all negative-polarity connection pads 122 in the third sub-solid region B41 are directly electrically connected to the fourth negative-polarity wiring 1244. The third positive-polarity lead wire 1333 is arranged on the side of the third negative-polarity lead wire 1343 proximate to the hollow region AA, and the fourth negative-polarity lead wire 1344 is arranged on the side of the fourth positive-polarity lead wire 1334 proximate to the hollow region AA.

In some embodiments, the haptic feedback component provided by embodiments of the present disclosure can be integrated into products such as notebooks and monitors, and can be used as a display screen in many fields such as vehicle-mounted displays and consumer electronics, providing users with a rich and realistic haptic feedback experience.

Based on the same inventive concept, embodiments of the present disclosure further provide a haptic feedback display device, as shown in FIG. 27, including:
a cover plate 100;
a display module 200, arranged on a non-touch surface of the cover plate 100;
a haptic feedback component 300, arranged on the non-touch surface of the cover plate 100, and the haptic feedback component 300 is the haptic feedback component provided by embodiments of the present disclosure.

Since the principle of solving the problem by the haptic feedback device is similar to that of the aforementioned haptic feedback component, the implementation of the haptic feedback device can refer to the implementation of the aforementioned haptic feedback component, and the repeated parts will not be repeated.

In some embodiments, in the above-mentioned haptic feedback device provided by embodiments of the present disclosure, as shown in FIG. 27, the cover plate 100 includes a central region aa (i.e., a display region) and a peripheral region bb surrounding the central region, the display module 200 is arranged in the central region of the cover plate 100, the hollow region AA of the haptic feedback component 300 corresponds to the central region aa of the cover plate, and the solid region BB of the haptic feedback component 300 corresponds to the peripheral region bb of the cover plate.

In some embodiments, the PCB can generate a driving signal based on the touch information of the touch object (such as a finger) on the cover plate 100 and transmit it to the piezoelectric actuator 2. The piezoelectric actuator 2 responds to the driving signal and drives the cover plate 100 to vibrate, thereby forming haptic feedback on the touch surface of the cover plate 100.

In some embodiments, in the above-mentioned haptic feedback device provided by embodiments of the present disclosure, as shown in FIG. 27, the cover plate 100 is a structure that directly contacts the haptic feedback sense organs such as fingers, and can be a cover plate on the surface of a notebook display module, a cover plate on the surface of a vehicle display module, a cover plate on the surface of a mobile terminal display module, or a cover plate on the surface of a display module for other application scenarios, etc.

It should be noted that the haptic feedback display device shown in FIG. 27 takes the haptic feedback component 300 as the structure shown in FIG. 1 as an example. Of course, the haptic feedback component 300 in the haptic feedback display device provided by embodiments of the present disclosure can also adopt the structure shown in FIGS. 9, 12, 17, 18, and 19, and the structure of the cover plate 100 needs to be changed accordingly to match the haptic feedback component 300.

In some embodiments, the display module in the above-mentioned haptic feedback display device provided by embodiments of the present disclosure can be a liquid crystal display module or a self-luminous display module, which is not limited in the present disclosure. Among them, the liquid crystal display module includes a liquid crystal display panel and a backlight source, and the self-luminous display module has a built-in light-emitting device, which can be, for example, an organic light-emitting diode (OLED), a quantum dot light-emitting diode (QLED), a sub-millimeter light-emitting diode (Mini LED) or a micro light-emitting diode (Micro LED), etc.

In some embodiments, the display module in the above-mentioned haptic feedback display device provided by embodiments of the present disclosure can further include a touch function layer.

In some embodiments, the haptic feedback display device provided by embodiments of the present disclosure can be a mobile phone, a tablet computer, a smart wearable device (such as a smart watch), a car display screen, etc.

In some embodiments, the haptic feedback display device shown in FIG. 27 provided in embodiments of the present disclosure can be a curved display screen, which is curved up and down, for example, with a curvature of R800, but is certainly not limited thereto.

Other essential components of the haptic feedback display device should be understood by those skilled in the art and will not be elaborated herein and should not be construed as limiting the present disclosure.

In some embodiments, the haptic feedback display device includes but is not limited to: a radio frequency unit, a network module, an audio output & input unit, a sensor, a display unit, a user input unit, an interface unit, a memory, a processor, and a power supply.

In addition, those skilled in the art can understand that the above structure does not constitute a limitation on the above haptic feedback display device provided by embodiments of the present disclosure. In other words, the above haptic feedback display device provided by embodiments of the present disclosure can include more or fewer of the above components, or a combination of certain components, or different component arrangements.

Embodiments of the present disclosure provide a haptic feedback component and a haptic feedback display device, different groups of piezoelectric actuators are connected to corresponding input pad groups by means of an FPC, and the input pad groups can be connected to an external PCB. Since the FPC can be wired on both sides, when the haptic feedback component of the present disclosure is integrated with a display or touch substrate, the space occupied by the wiring connecting the piezoelectric actuators in the frame region of the substrate can be reduced, thereby achieving a narrow frame; and by reasonably arranging the way in which the piezoelectric actuators are connected to the PCB by means of wiring, the noise generated by the wiring as the piezoelectric actuators vibrate can also be reduced.

Although the preferred embodiments of the disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of this disclosure.

Obviously, those skilled in the art can make various changes and modifications to embodiments of the disclosures without departing from the spirit and scope of embodiments of the disclosures. In this way, if these modifications and variations of the embodiments of the disclosure fall within the scope of the claims of the disclosure and equivalent technologies, the disclosure is also intended to include these modifications and variations.

1. A haptic feedback component, comprising:
a flexible circuit board, comprising: a flexible substrate, a first metal layer arranged on a first surface of the flexible substrate, and a second metal layer arranged on a second surface of the flexible substrate; wherein the first surface and the second surface are arranged opposite to each other along a thickness direction of the flexible substrate; the first metal layer comprises a plurality of connection pad groups, and the second metal layer comprises at least one input pad group;
a plurality of piezoelectric actuators, arranged on a side of the first metal layer facing away from the flexible substrate, wherein each of the plurality of piezoelectric actuators is electrically connected to one of the plurality of connection pad groups; the plurality of piezoelectric actuators are divided into at least one group, the piezoelectric actuators in a same group are electrically connected to a same input pad group, and the piezoelectric actuators in different groups are electrically connected to different input pad groups; the plurality of piezoelectric actuators are configured to generate haptic feedback in response to a drive signal input by the at least one input pad group.

2. The haptic feedback component according to claim 1, wherein each of the plurality of piezoelectric actuators is provided with a positive-polarity lead-out structure and a negative-polarity lead-out structure on a side facing the first metal layer,
each of the plurality of connection pad groups comprises a positive-polarity connection pad and a negative-polarity connection pad; and
the positive-polarity lead-out structure is electrically connected to the positive-polarity connection pad, and the negative-polarity lead-out structure is electrically connected to the negative-polarity connection pad;
each of the at least one input pad group comprises a positive-polarity input pad, the first metal layer further comprises a positive-polarity wiring, and the second metal layer further comprises a positive-polarity lead wire;
each of the positive-polarity connection pads electrically connected to the piezoelectric actuators in the same group is electrically connected to a corresponding positive-polarity input pad by means of at least one positive-polarity wiring and at least one positive-polarity lead wire.

3. The haptic feedback component according to claim 2, wherein each of the at least one input pad group further comprises a negative-polarity input pad, the first metal layer further comprises a negative-polarity wiring, and the second metal layer further comprises a negative-polarity lead wire;
each of the negative-polarity connection pads electrically connected to the piezoelectric actuators in the same group is electrically connected to a corresponding negative-polarity input pad by means of at least one negative-polarity wiring and at least one negative-polarity lead wire.

4. The haptic feedback component according to claim 3, wherein the positive-polarity wiring and the positive-polarity lead wire electrically connected to the piezoelectric actuators in the same group are electrically connected by means of a first via hole penetrating through the flexible substrate; and
the negative-polarity wiring and the negative-polarity lead wire electrically connected to the piezoelectric actuators in the same group are electrically connected by means of a second via hole penetrating through the flexible substrate.

5. The haptic feedback component according to claim 4, wherein the flexible circuit board comprises a hollow region and a solid region surrounding the hollow region, and the plurality of connection pad groups are arranged around the hollow region;
the solid region comprises a first solid region and a second solid region located on opposite sides of the hollow region in a first direction, and the solid region further comprises a third solid region and a fourth solid region located on opposite sides of the hollow region in a second direction, and the first direction is perpendicular to the second direction;
the plurality of piezoelectric actuators comprise: a first group of piezoelectric actuators located in the first solid region and the second solid region, and a second group of piezoelectric actuators located in the third solid region and the fourth solid region;
the plurality of piezoelectric actuators in the first solid region are arranged in at least one row, and the plurality of piezoelectric actuators in the second solid region are arranged in at least one row, and the plurality of piezoelectric actuators in each row are arranged in sequence along the second direction;
the plurality of piezoelectric actuators in the third solid region are arranged in at least one column, and the plurality of piezoelectric actuators in the fourth solid region are arranged in at least one column, and the plurality of piezoelectric actuators in each column are arranged in sequence along the first direction.

6. The haptic feedback component according to claim 5, wherein the positive-polarity wiring and the negative-polarity wiring corresponding to the first group of piezoelectric actuators are insulated from each other, and the positive-polarity wiring and the negative-polarity wiring corresponding to the second group of piezoelectric actuators are insulated from each other;
the positive-polarity lead wire and the negative-polarity lead wire corresponding to the first group of piezoelectric actuators are insulated from each other; and the positive-polarity lead wire and the negative-polarity lead wire corresponding to the second group of piezoelectric actuators are insulated from each other.

7. The haptic feedback component according to claim 5, wherein, in the first solid region, the second solid region, the third solid region and the fourth solid region, the piezoelectric actuators correspond one-to-one with the connection pad groups;
the positive-polarity connection pads corresponding to the piezoelectric actuators in a same row in the first solid region and the second solid region are arranged in a same row and arranged along the second direction, and the negative-polarity connection pads corresponding to the piezoelectric actuators in the same row in the first solid region and the second solid region are arranged in a same row and arranged along the second direction;
the positive-polarity connection pads corresponding to the piezoelectric actuators in a same column in the third solid region and the fourth solid region are arranged in a same column and arranged along the first direction, and the negative-polarity connection pads corresponding to the piezoelectric actuators in the same column in the third solid region and the fourth solid region are arranged in a same column and arranged along the first direction.

8. The haptic feedback component according to claim 5, wherein the third solid region is divided into a first sub-solid region and a second sub-solid region along the first direction, and the fourth solid region is divided into a third sub-solid region and a fourth sub-solid region along the first direction, the first sub-solid region and the third sub-solid region are proximate to the second solid region, and the second sub-solid region and the fourth sub-solid region are proximate to the first solid region;
the second group of piezoelectric actuators comprises: a first sub-group of piezoelectric actuators located in the first sub-solid region and the third sub-solid region, and a second sub-group of piezoelectric actuators located in the second sub-solid region and the fourth sub-solid region;
the positive-polarity wiring and the negative-polarity wiring corresponding to the first sub-group of piezoelectric actuators and the positive-polarity wiring and the negative-polarity wiring corresponding to the second sub-group of piezoelectric actuators are different; and the positive-polarity lead wire and the negative-polarity lead wire corresponding to the first sub-group of piezoelectric actuators and the positive-polarity lead wire and the negative-polarity lead wire corresponding to the second sub-group of piezoelectric actuators are different.

9. The haptic feedback component according to claim 8, wherein, in the first sub-solid region, the positive-polarity connection pads corresponding to the piezoelectric actuators in different columns are aligned along the second direction;
in the third sub-solid region, the positive-polarity connection pads corresponding to the piezoelectric actuators in different columns are aligned along the second direction;
in the first sub-solid region, the negative-polarity connection pads corresponding to the piezoelectric actuators in different columns are aligned along the second direction;
in the third sub-solid region, the negative-polarity connection pads corresponding to the piezoelectric actuators in different columns are aligned along the second direction;
in the first sub-solid region, the positive-polarity connection pads and the negative-polarity connection pads in a same column are alternately arranged along the first direction;
in the third sub-solid region, the positive-polarity connection pads and the negative-polarity connection pads in a same column are alternately arranged along the first direction.

10. The haptic feedback component according to claim 8, wherein the plurality of piezoelectric actuators in the first sub-solid region are arranged in a same column and arranged in sequence along the first direction, the negative-polarity connection pads of the piezoelectric actuators in the first sub-solid region are proximate to an outer edge of the first sub-solid region and arranged along the first direction, and the positive-polarity connection pads of the piezoelectric actuators in the first sub-solid region are proximate to an inner edge of the first sub-solid region and arranged along the first direction;
the plurality of piezoelectric actuators in the third sub-solid region are arranged in a same column and arranged in sequence along the first direction, the negative-polarity connection pads of the piezoelectric actuators in the third sub-solid region are proximate to an outer edge of the third sub-solid region and arranged along the first direction, and the positive-polarity connection pads of the piezoelectric actuators in the third sub-solid region are proximate to an inner edge of the third sub-solid region and arranged along the first direction.

11. The haptic feedback component according to claim 8, wherein the positive-polarity connection pads located in the second sub-solid region are arranged in a same column and are arranged sequentially along the first direction;
the negative-polarity connection pads located in the second sub-solid region are arranged in a same column and are arranged sequentially along the first direction;
the positive-polarity connection pads and the negative-polarity connection pads are arranged in different columns, and the positive-polarity connection pads and the negative-polarity connection pads are alternately arranged along the first direction.

12. The haptic feedback component according to claim 11, wherein the positive-polarity connection pads located in the fourth sub-solid region are arranged in a same column and are arranged sequentially along the first direction;
the negative-polarity connection pads located in the fourth sub-solid region are arranged in a same column and are arranged sequentially along the first direction;
the positive-polarity connection pads and the negative-polarity connection pads are arranged in different columns, and the positive-polarity connection pads and the negative-polarity connection pads are alternately arranged along the first direction.

13. The haptic feedback component according to claim 8, wherein the solid region further comprises a fifth solid region, the fifth solid region is located on a side of the first solid region away from the second solid region, and the at least one input pad group is located in the fifth solid region.

14. The haptic feedback component according to claim 13, wherein the fifth solid region is located at an edge of the first solid region and proximate to the third solid region; or
the fifth solid region is located at an edge of the first solid region and proximate to the fourth solid region; or
the fifth solid region is located in a middle region of the first solid region.

15. The haptic feedback component according to claim 14, wherein the at least one input pad group comprises: a first input pad group corresponding to the first group of piezoelectric actuators, a second input pad group corresponding to the first sub-group of piezoelectric actuators, and a third input pad group corresponding to the second sub-group of piezoelectric actuators.

16. The haptic feedback component according to claim 8, wherein the at least one input pad group comprises:
a first input pad group located in the first solid region and corresponding to the piezoelectric actuators in the first solid region;
a second input pad group located in the second solid region and corresponding to the piezoelectric actuators in the second solid region;
a third input pad group located in the first sub-solid region and corresponding to the piezoelectric actuators in the first sub-solid region;
a fourth input pad group located in the third sub-solid region and corresponding to the piezoelectric actuators in the third sub-solid region;
a fifth input pad group located in the second sub-solid region and corresponding to the piezoelectric actuators in the second sub-solid region; and
a sixth input pad group located in the fourth sub-solid region and corresponding to the piezoelectric actuators in the fourth sub-solid region.

17. The haptic feedback component according to claim 16, wherein the first input pad group is located at one end of the first solid region, and the second input pad group is located at one end of the second solid region;
the third input pad group is located at one end of the first sub-solid region, the fourth input pad group is located at one end of the third sub-solid region, and the third input pad group and the fourth input pad group are proximate to the second solid region;
the fifth input pad group is located at one end of the second sub-solid region, the sixth input pad group is located at one end of the fourth sub-solid region, and the fifth input pad group and the sixth input pad group are proximate to the first solid region.

18. The haptic feedback component according to claim 1, wherein a shape of the piezoelectric actuator comprises a rectangle or a circle; and
a structure of the piezoelectric actuator is a piezoelectric film or a piezoelectric ceramic block.

19. A haptic feedback display device, comprising:
a cover plate;
a display module, arranged on a non-touch surface of the cover plate;
a haptic feedback component, arranged on the non-touch surface of the cover plate, and the haptic feedback component is the haptic feedback component according to claim 1.

20. The haptic feedback display device according to claim 19, wherein the cover plate comprises a central region and a peripheral region surrounding the central region;
the display module is arranged in the central region of the cover plate;
a hollow region of the haptic feedback component corresponds to the central region of the cover plate; and
a solid region of the haptic feedback component corresponds to the peripheral region of the cover plate.
